(19) United States
(12) Patent Application Publication
(10) Pub. No.: US 2015/0155514 A1
(43) Pub. Date: Jun. 4, 2015

(54) ORGANIC ELECTROLUMINESCENCE DEVICE

(71) Applicant: Merck Patent GmbH, Darmstadt (DE)

(72) Inventors: Joachim Kaiser, Darmstadt (DE); Horst VESTWEBER, Gilserberg-Winterscheid (DE); Simone LEU, Dittelsheim-Hessloch (DE)

(21) Appl. No.: 14/594,513

(22) Filed: Jan. 12, 2015

Related U.S. Application Data
(63) Continuation of application No. 13/147,186, filed on Jul. 29, 2011.

(30) Foreign Application Priority Data
Mar. 9, 2009 (DE) 102009012346.6

(51) Int. Cl. H01L 51/50; H01L 51/52; H01L 51/56; H01L 51/00

(52) U.S. Cl. CPC H01L 51/504; H01L 51/006; H01L 51/0085; H01L 51/0058; H01L 51/0072; H01L 51/0067; H01L 51/0056; H01L 51/0054; H01L 51/5203; H01L 51/508; H01L 51/5092; H01L 51/56; H01L 51/0003; H01L 51/0004; H01L 51/0008; H01L 51/0002

(57) ABSTRACT

The present invention relates to white-emitting organic electroluminescent devices in which the dependence of the colour point on the luminance can be adjusted specifically.

The present invention relates to white-emitting organic electroluminescent devices.

Organic semiconductors are being developed for a number of electronic applications of different types. The structure of organic electroluminescent devices (OLEDs) in which these organic semiconductors are employed as functional materials is described, for example, in U.S. Pat. No. 4,539,507, U.S. Pat. No. 5,151,629, EP 0676461 and WO 98/27136. A development in the area of organic electroluminescent devices is white-emitting OLEDs. These can be employed either for monochrome white displays or, with coloured filters, for full-colour displays. They are furthermore suitable for lighting applications. White-emitting organic electroluminescent devices based on low-molecular-weight compounds generally have at least two emission layers. They frequently have at least three emission layers, which exhibit blue, green and red emission. Either fluorescent or phosphorescent emitters are used in the emission layers, where the phosphorescent emitters exhibit significant advantages owing to the higher achievable efficiency. The general structure of a white-emitting OLED of this type having at least one phosphorescent layer is described, for example, in WO 05/011013.

However, there is still a need for improvement in white-emitting OLEDs. The strong dependence of the colour point on the applied voltage is regarded as particularly problematical for many applications, i.e. the colour point is highly luminance-dependent.

The technical object on which the present invention is based therefore consists in the provision of a white-emitting organic electroluminescent device in which the colour point exhibits reduced luminance dependence. A further object consists in the provision of a method which enables the luminance dependence of the colour point of a white-emitting organic electroluminescent device to be improved.

For some applications, it may also be desirable for the colour point to change as a function of the luminance. In these cases, however, the colour shift should be adjustable in a specific and controllable manner. A further technical object on which the present invention is based therefore consists in the provision of a white-emitting organic electroluminescent device in which the colour shift can be adjusted specifically as a function of the luminance.

Surprisingly, it has been found that the colour point of a white-emitting organic electroluminescent device which has at least two, preferably at least three, emitting layers exhibits a particularly low dependence on the luminance if the blue emission layer is arranged on the cathode side and if at least two electron-transport layers which comprise different materials are present between the cathode and the blue emission layer. It has furthermore been found that the dependence of the colour shift on the luminance can be adjusted specifically depending on the layer thickness of the layer directly adjacent to the blue emission layer. Particularly good success has been achieved if the electron-transport material which is directly adjacent to the blue-emitting layer is an aromatic ketone, an aromatic phosphine oxide, an aromatic sulfone, an aromatic sulfoxide or a triazine derivative.

The prior art discloses organic electroluminescent devices which comprise aromatic ketones, aromatic phosphine oxides, aromatic sulfones or aromatic sulfoxides in the electron-transport layer (WO 05/084081, WO 05/084082). Although the use of these materials for white-emitting electroluminescent devices is also generally disclosed therein, it is, however, not disclosed that it is advantageous to employ these materials in combination with a further electron-transport layer and that these materials result in a reduction in the luminance dependence of the colour point of a white-emitting OLED in this device configuration and that the colour shift can be adjusted specifically as a function of the luminance with these materials.

WO 05/054403 discloses the use of ketones, phosphine oxides, sulfones and sulfoxides as hole-blocking material for phosphorescent organic electroluminescent devices. The device structure mentioned above for white-emitting OLEDs is not disclosed. However, the effect of these materials on the luminance dependence of the colour point of a white-emitting organic electroluminescent device is not evident therefrom, but instead merely the influence on the efficiency and lifetime in electroluminescent devices which have only one emission layer is presented.

US 2008/0318084 discloses a white-emitting organic electroluminescent device which comprises a layer which stabilises the colour shift between the green-emitting layer and the electron-transport layer. However, it is not evident from this application how this colour-stabilisation layer differs from a hole-blocking layer, in particular in a phosphorescent device. Since neither specific materials for this colour-stabilisation layer nor the precise device structure are disclosed, it is not possible to reproduce the results given in the application.

The invention thus relates to an organic electroluminescent device comprising, in this sequence, an anode, a yellow- or red-emitting layer, a blue-emitting layer and a cathode, characterised in that at least one electron-transport layer 1, which is adjacent to the blue-emitting layer, and an electron-transport layer 2, which is adjacent to the cathode or the electron-injection layer, are introduced between the blue-emitting layer and the cathode.

The compositions of the electron-transport layer 1 and electron-transport layer 2 are different here, i.e. these layers comprise different materials.

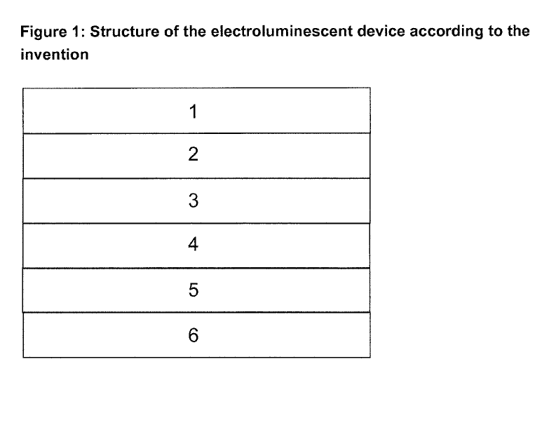

The general device structure is depicted diagrammatically in FIG. 1. Layer 1 here stands for the anode, layer 2 for the yellow- to red-emitting layer, layer 3 for the blue-emitting layer, layer 4 for the electron-transport layer 1, layer 5 for the electron-transport layer 2 and layer 6 for the cathode. The organic electroluminescent device here does not necessarily have to comprise only layers built up from organic or organometallic materials. Thus, it is also possible for the anode, cathode and/or one or more layers to comprise inorganic materials or to be built up entirely from inorganic materials.

In a preferred embodiment of the invention, the electroluminescent device according to the invention has at least three emitting layers.

The emitting layers can be directly adjacent to one another in the electroluminescent device according to the invention, or they can be separated from one another by interlayers.

A preferred embodiment of the invention relates to a white-emitting organic electroluminescent device. This is characterised in that it emits light having CIE colour coordinates in the range from 0.28/0.29 to 0.45/0.41.

If the organic electroluminescent device has precisely two emitting layers, the emitting layer on the anode side is preferably a yellow- or orange-emitting layer.

If the organic electroluminescent device has three emitting layers, one of these layers is preferably a red- or orange-emitting layer and one of the layers is a green-emitting layer. The red- or orange-emitting layer is preferably then on the anode side and the green-emitting layer is between the red-emitting layer and the blue-emitting layer.

A yellow-emitting layer here is taken to mean a layer whose photoluminescence maximum is in the range from 540 to 570 nm. An orange-emitting layer is taken to mean a layer whose photoluminescence maximum is in the range from 570 to 600 nm. A red-emitting layer is taken to mean a layer whose photoluminescence maximum is in the range from 600 to 750 nm. A green-emitting layer is taken to mean a layer whose photoluminescence maximum is in the range from 490 to 540 nm. A blue-emitting layer is taken to mean a layer whose photoluminescence maximum is in the range from 440 to 490 nm. The photoluminescence maximum here is determined by measurement of the photoluminescence spectrum of the layer having a layer thickness of 50 nm.

In accordance with the invention, the organic electroluminescent device comprises at least two electron-transport layers between the blue-emitting layer and the cathode, where the electron-transport layer 1 is adjacent to the blue-emitting layer and the electron-transport layer 2 is adjacent to the cathode.

The materials which are preferably used in the two electron-transport layers are indicated below.

Preferred materials for the electron-transport layer 1, which is directly adjacent to the blue-emitting layer, are aromatic ketones, aromatic phosphine oxides, aromatic sulfoxides, aromatic sulfones, triazine derivatives, metal complexes, in particular aluminium or zinc complexes, anthracene derivatives, benzimidazole derivatives, metal benzimidazole derivatives and metal hydroxyquinoline complexes. The best results are obtained with aromatic ketones and triazine derivatives, and consequently these classes of material are preferred.

The preferred layer thickness for the electron-transport layer 1 is in the range from 3 to 20 nm.

For the purposes of this application, an aromatic ketone is taken to mean a carbonyl group to which two aromatic or heteroaromatic groups or aromatic or heteroaromatic ring systems are bonded directly. Aromatic phosphine oxides, sulfones and sulfoxides are defined analogously.

In a particularly preferred embodiment of the invention, the material for the electron-transport layer 1 is an aromatic ketone of the following formula (1):

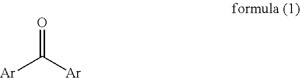

where the following applies to the symbols used:
Ar is on each occurrence, identically or differently, an aromatic or heteroaromatic ring system having 5 to 60 aromatic ring atoms, which may in each case be substituted by one or more groups R¹;
R¹ is on each occurrence, identically or differently, H, D, F, Cl, Br, I, CHO, C(═O)Ar¹, P(═O)(Ar¹)₂, S(═O)Ar¹, S(═O)₂Ar¹, CR²═CR²Ar¹, CN, NO₂, Si(R²)₃, B(OR²)₂, B(R²)₂, B(N(R²)₂)₂, OSO₂R², a straight-chain alkyl, alkenyl, alkynyl, alkoxy or thioalkoxy group having 1 to 40 C atoms or a branched or cyclic alkyl, alkenyl, alkynyl, alkoxy or thioalkoxy group having 3 to 40 C atoms, each of which may be substituted by one or more radicals R², where one or more non-adjacent CH₂ groups may be replaced by R²C═CR², C≡C, Si(R²)₂, Ge(R²)₂, Sn(R²)₂, C═O, C═S, C═Se, C═NR², P(═O)(R²), SO, SO₂, NR², O, S or CONR² and where one or more H atoms may be replaced by D, F, CI, Br, I, CN or NO₂, or an aromatic or heteroaromatic ring system having 5 to 60 aromatic ring atoms, which may in each case be substituted by one or more radicals R², or an aryloxy or heteroaryloxy group having 5 to 60 aromatic ring atoms, which may be substituted by one or more radicals R², or a combination of these systems; two or more adjacent substituents R¹ here may also form a mono- or polycyclic, aliphatic or aromatic ring system with one another;
Ar¹ is on each occurrence, identically or differently, an aromatic or heteroaromatic ring system having 5 to 40 aromatic ring atoms, which may be substituted by one or more radicals R²;
R² is on each occurrence, identically or differently, H, D, CN or an aliphatic, aromatic and/or heteroaromatic hydrocarbon radical having 1 to 20 C atoms, in which, in addition, H atoms may be replaced by F; two or more adjacent substituents R² here may also form a mono- or polycyclic, aliphatic or aromatic ring system with one another.

For the purposes of this invention, an aryl group contains at least 6 C atoms; for the purposes of this invention, a heteroaryl group contains at least 2 C atoms and at least one heteroatom, with the proviso that the sum of C atoms and heteroatoms is at least 5. The heteroatoms are preferably selected from N, O and/or S. An aryl group or heteroaryl group here is taken to mean either a simple aromatic ring, i.e. benzene, or a simple heteroaromatic ring, for example pyridine, pyrimidine, thiophene, etc., or a condensed aryl or heteroaryl group, for example naphthalene, anthracene, pyrene, quinoline, isoquinoline, etc.

For the purposes of this invention, an aromatic ring system contains at least 6 C atoms in the ring system. For the purposes of this invention, a heteroaromatic ring system contains at least 2 C atoms and at least one heteroatom in the ring system, with the proviso that the sum of C atoms and heteroatoms is at least 5. The heteroatoms are preferably selected from N, O and/or S. For the purposes of this invention, an aromatic or heteroaromatic ring system is intended to be taken to mean a system which does not necessarily contain only aryl or heteroaryl groups, but instead in which, in addition, a plurality of aryl or heteroaryl groups may be interrupted by a short non-aromatic unit (preferably less than 10% of the atoms other than H), such as, for example, an sp³-hybridised C, N or O atom or a carbonyl group. Thus, for example, systems such as 9,9′-spirobifluorene, 9,9-diarylfluorene, triarylamine, diaryl ether, stilbene, benzophenone, etc., are also intended to be taken to be aromatic ring systems for the purposes of this invention. An aromatic or heteroaromatic ring system is likewise taken to mean systems in which a plurality of aryl or heteroaryl groups are linked to one another by single bonds, for example biphenyl, terphenyl or bipyridine.

For the purposes of the present invention, a C₁- to C₄₀-alkyl group, in which, in addition, individual H atoms or CH₂ groups may be substituted by the above-mentioned groups, is particularly preferably taken to mean the radicals methyl, ethyl, n-propyl, i-propyl, n-butyl, i-butyl, s-butyl, t-butyl, 2-methylbutyl, n-pentyl, s-pentyl, tert-pentyl, 2-pentyl, neopentyl, cyclopentyl, n-hexyl, s-hexyl, tert-hexyl, 2-hexyl, 3-hexyl, neohexyl, cyclohexyl, 2-methylpentyl, n-heptyl, 2-heptyl, 3-heptyl, 4-heptyl, cycloheptyl, 1-methyl-cyclohexyl, n-octyl, 2-ethylhexyl, cyclooctyl, 1-bicyclo[2.2.2]octyl, 2-bicyclo-[2.2.2]octyl, 2-(2,6-dimethyl)octyl, 3-(3,7-dimethyl)octyl, trifluoromethyl, pentafluoroethyl and 2,2,2-trifluoroethyl. A C₁- to C₄₀-alkenyl group is preferably taken to mean ethenyl, propenyl, butenyl, pentenyl, cyclopentenyl, hexenyl, cyclohexenyl, heptenyl, cycloheptenyl, octenyl and cyclooctenyl. A C1- to C40-alkynyl group is preferably taken to mean ethynyl, propynyl, butynyl, pentynyl, hexynyl, heptynyl or octynyl. A C₁- to C₄₀-alkoxy group is particularly preferably taken to mean methoxy, trifluoromethoxy, ethoxy, n-propoxy, i-propoxy, n-butoxy, i-butoxy, s-butoxy, t-butoxy or 2-methyl-butoxy. An aromatic or heteroaromatic ring system having 5-60 aromatic ring atoms, which may also in each case be substituted by the above-mentioned radicals R and which may be linked to the aromatic or heteroaromatic ring system via any desired positions, is taken to mean, in particular, groups derived from benzene, naphthalene, anthracene, phenanthrene, benzanthracene, pyrene, chrysene, perylene, fluoranthene, benzofluoranthene, naphthacene, pentacene, benzopyrene, biphenyl, biphenylene, terphenyl, terphenylene, fluorene, benzofluorene, dibenzofluorene, spirobifluorene, dihydrophenanthrene, dihydropyrene, tetrahydropyrene, cis- or trans-indenofluorene, cis- or trans-monobenzoindenofluorene, cis- or trans-dibenzoindenofluorene, truxene, isotruxene, spirotruxene, spiroisotruxene, furan, benzofuran, isobenzofuran, dibenzofuran, thiophene, benzo-thiophene, isobenzothiophene, dibenzothiophene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubin, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole.

The compounds of the formula (1) preferably have a glass transition temperature T_{G} of greater than 70° C., particularly preferably greater than 90° C., very particularly preferably greater than 110° C.

It is evident from the definition of the compound of the formula (1) that this does not have to contain only one carbonyl group, but instead may also contain a plurality of these groups.

The group Ar in compounds of the formula (1) is preferably an aromatic ring system having 6 to 40 aromatic ring atoms, i.e. it does not contain any heteroaryl groups. As defined above, the aromatic ring system does not necessarily have to contain only aromatic groups, but instead two aryl groups may also be interrupted by a non-aromatic group, for example by a further carbonyl group.

In a further preferred embodiment of the invention, the group Ar does not contain any aryl or heteroaryl groups having more than two condensed rings. It is thus preferably built up only from phenyl and/or naphthyl groups, particularly preferably only from phenyl groups, but does not contain any larger condensed aromatic groups, such as, for example, anthracene.

Preferred groups Ar which are bonded to the carbonyl group are phenyl, 2-, 3- or 4-tolyl, 3- or 4-o-xylyl, 2- or 4-m-xylyl, 2-p-xylyl, o-, m- or p-tert-butylphenyl, o-, m- or p-fluorophenyl, benzophenone, 1-, 2- or 3-phenylmethanone, 2-, 3- or 4-biphenyl, 2-, 3- or 4-o-terphenyl, 2-, 3- or 4-m-terphenyl, 2-, 3- or 4-p-terphenyl, 2′-p-terphenyl, 2′-, 4′- or 5′-m-terphenyl, 3′- or 4′-o-terphenyl, p-, m,p-, o,p-, m,m-, o,m- or o,o-quaterphenyl, quinquephenyl, sexiphenyl, 1-, 2-, 3- or 4-fluorenyl, 2-, 3- or 4-spiro-9,9′-bifluorenyl, 1-, 2-, 3- or 4-(9,10-dihydro)phenanthrenyl, 1- or 2-naphthyl, 2-, 3-, 4-, 5-, 6-, 7- or 8-quinolinyl, 1-, 3-, 4-, 5-, 6-, 7- or 8-isoquinolinyl, 1- or 2-(4-methylnaphthyl), 1- or 2-(4-phenylnaphthyl), 1- or 2-(4-naphthylnaphthyl), 1-, 2- or 3-(4-naphthylphenyl), 2-, 3- or 4-pyridyl, 2-, 4- or 5-pyrimidinyl, 2- or 3-pyrazinyl, 3- or 4-pyridazinyl, 2-(1,3,5-triazin)yl, 2-, 3- or 4-(phenyl-pyridyl), 3-, 4-, 5- or 6-(2,2′-bipyridyl), 2-, 4-, 5- or 6-(3,3′-bipyridyl), 2- or 3-(4,4′-bipyridyl) and combinations of one or more of these radicals.

The above-mentioned groups Ar may be substituted by one or more radicals R¹. These radicals R¹ are preferably selected, identically or differently on each occurrence, from the group consisting of H, D, F, C(═O)Ar¹, P(═O)(Ar¹)₂, S(═O)Ar¹, S(═O)₂Ar¹, a straight-chain alkyl group having 1 to 4 C atoms or a branched or cyclic alkyl group having 3 to 5 C atoms, each of which may be substituted by one or more radicals R², where one or more H atoms may be replaced by D or F, or an aromatic ring system having 6 to 24 aromatic ring atoms, which may be substituted by one or more radicals R², or a combination of these systems; two or more adjacent substituents R¹ here may also form a mono- or polycyclic, aliphatic or aromatic ring system with one another. If the organic electroluminescent device is applied from solution, straight-chain, branched or cyclic alkyl groups having up to 10 C atoms are also preferred as substituents R¹. The radicals R¹ are particularly preferably selected, identically or differently on each occurrence, from the group consisting of H, C(═O)Ar¹ or an aromatic ring system having 6 to 24 aromatic ring atoms, which may be substituted by one or more radicals R², but is preferably unsubstituted.

In a further preferred embodiment of the invention, the group Ar¹ is, identically or differently on each occurrence, an aromatic ring system having 6 to 24 aromatic ring atoms, which may be substituted by one or more radicals R². Ar¹ is particularly preferably, identically or differently on each occurrence, an aromatic ring system having 6 to 12 aromatic ring atoms.

Suitable compounds of the formula (1) are, in particular, the ketones disclosed in WO 04/093207 and the unpublished DE 102008033943.1. These are incorporated into the present invention by way of reference.

Examples of suitable compounds of the formula (1) are compounds (1) to (59) depicted below.

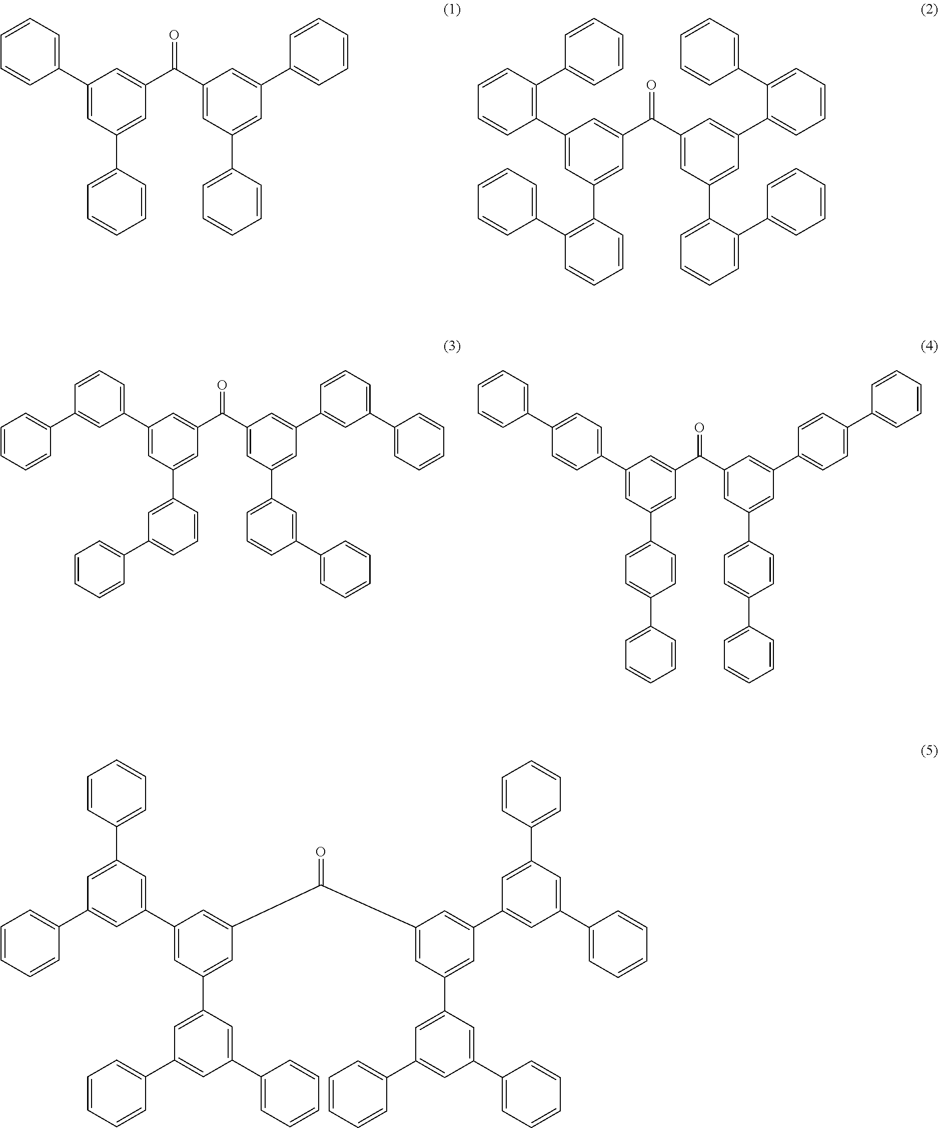

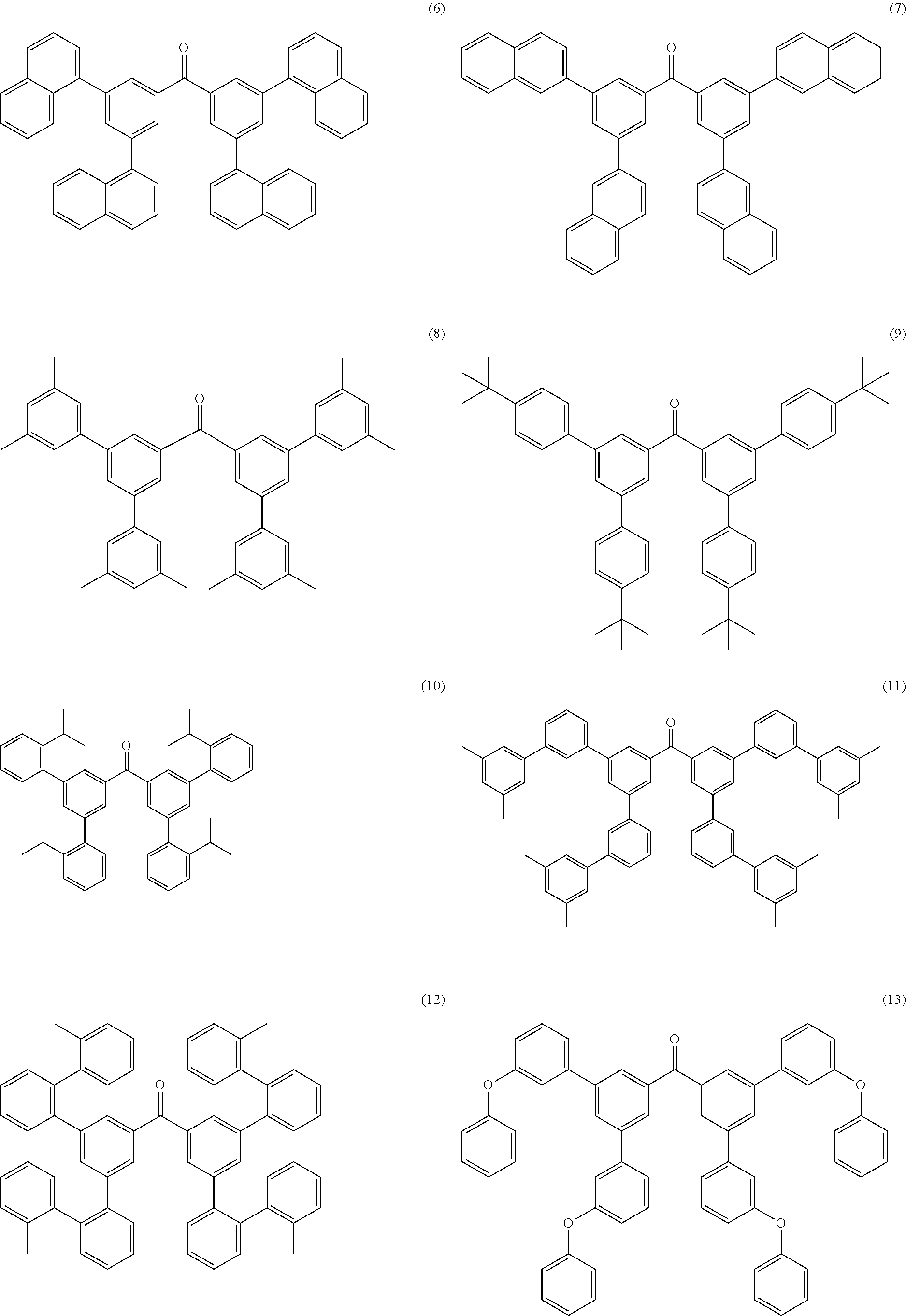

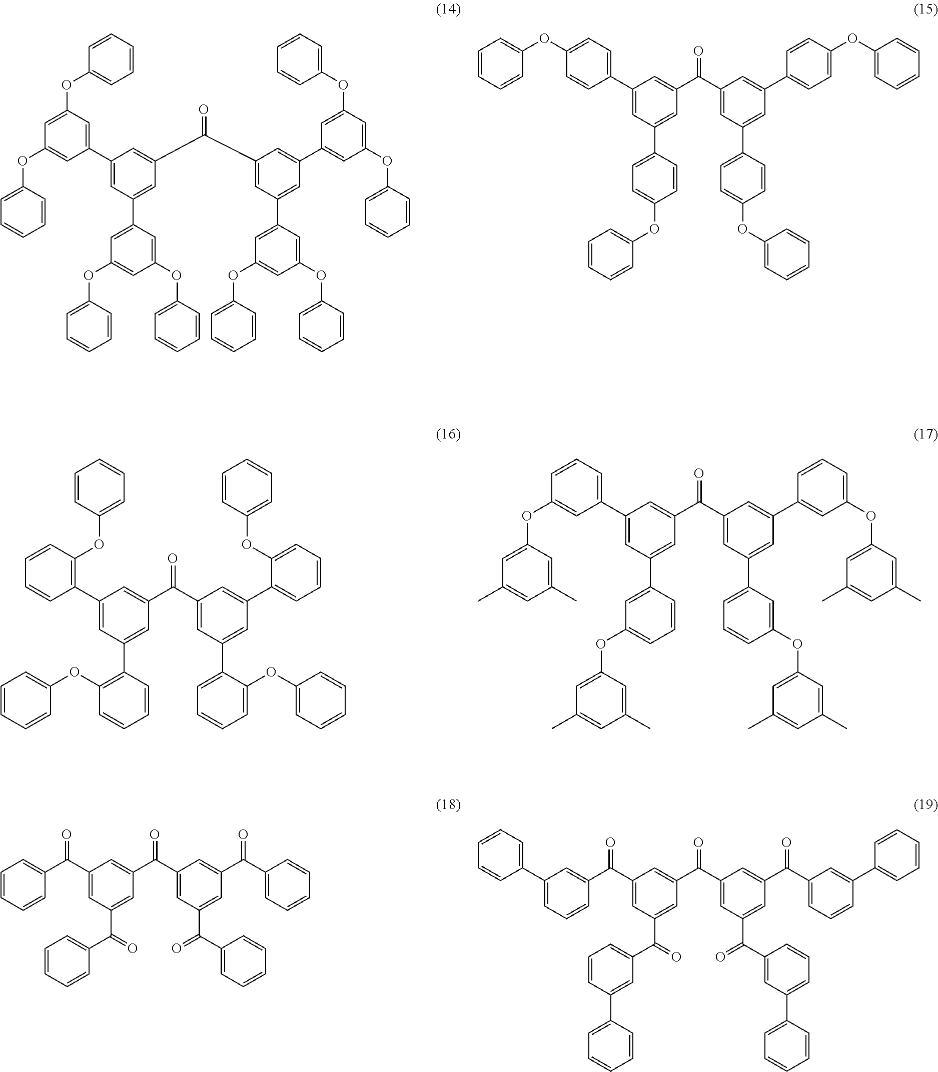

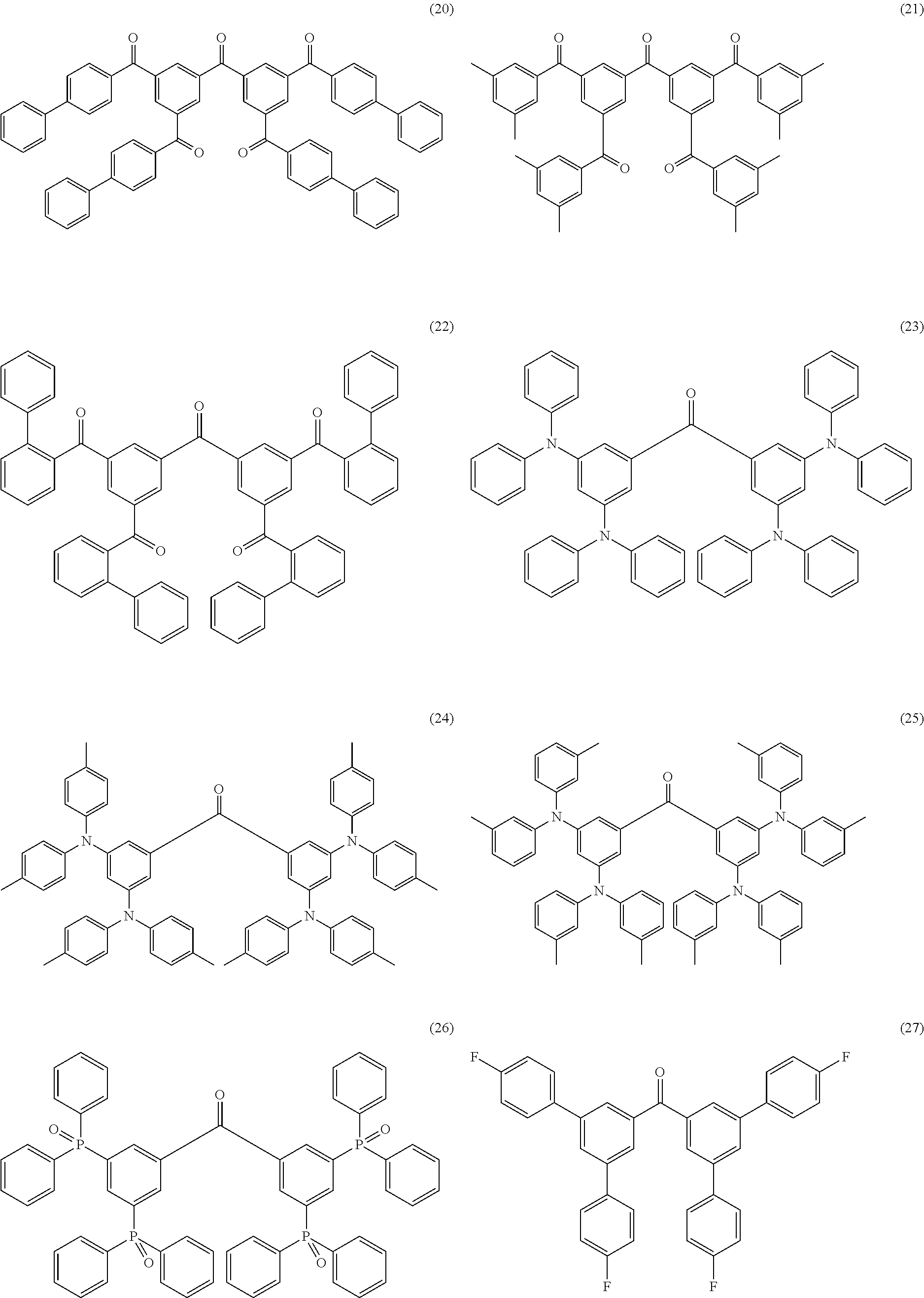

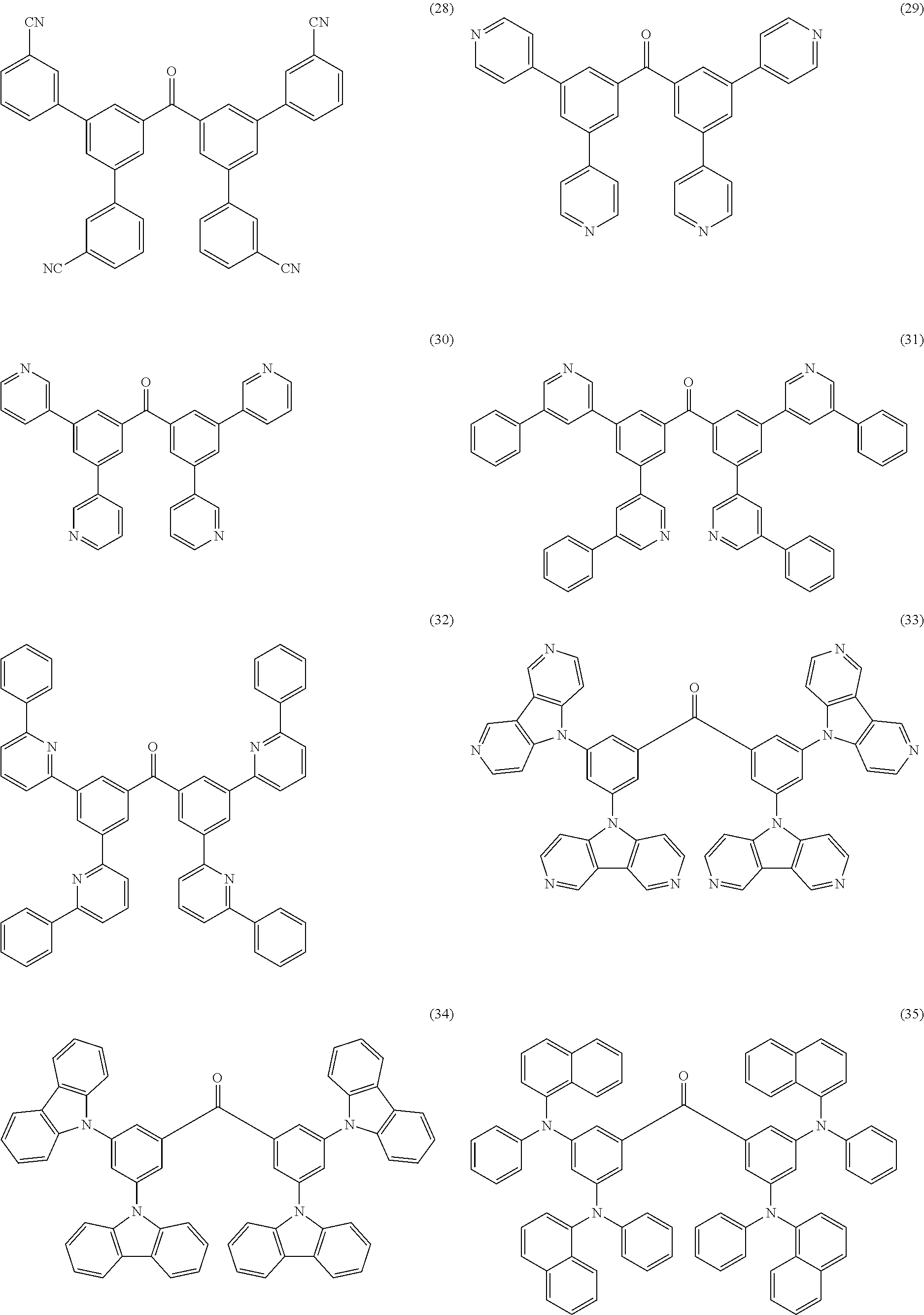

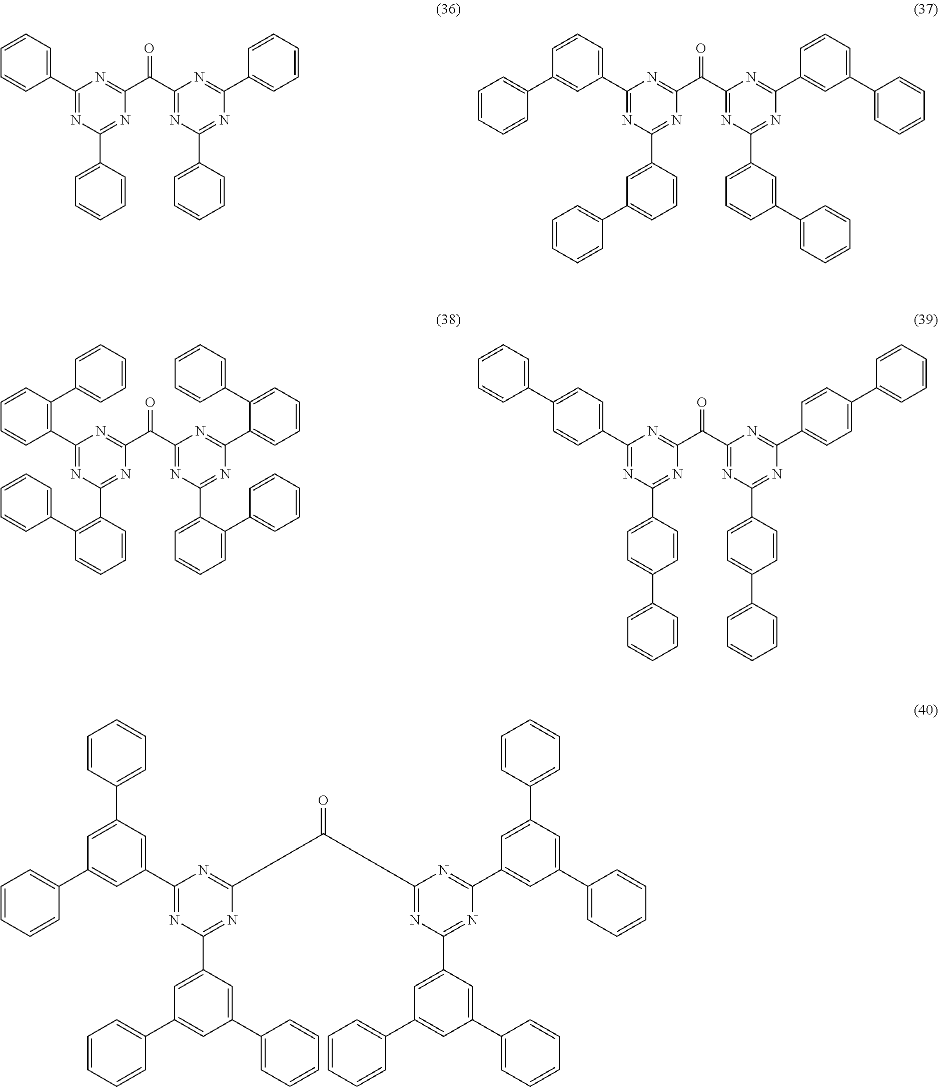

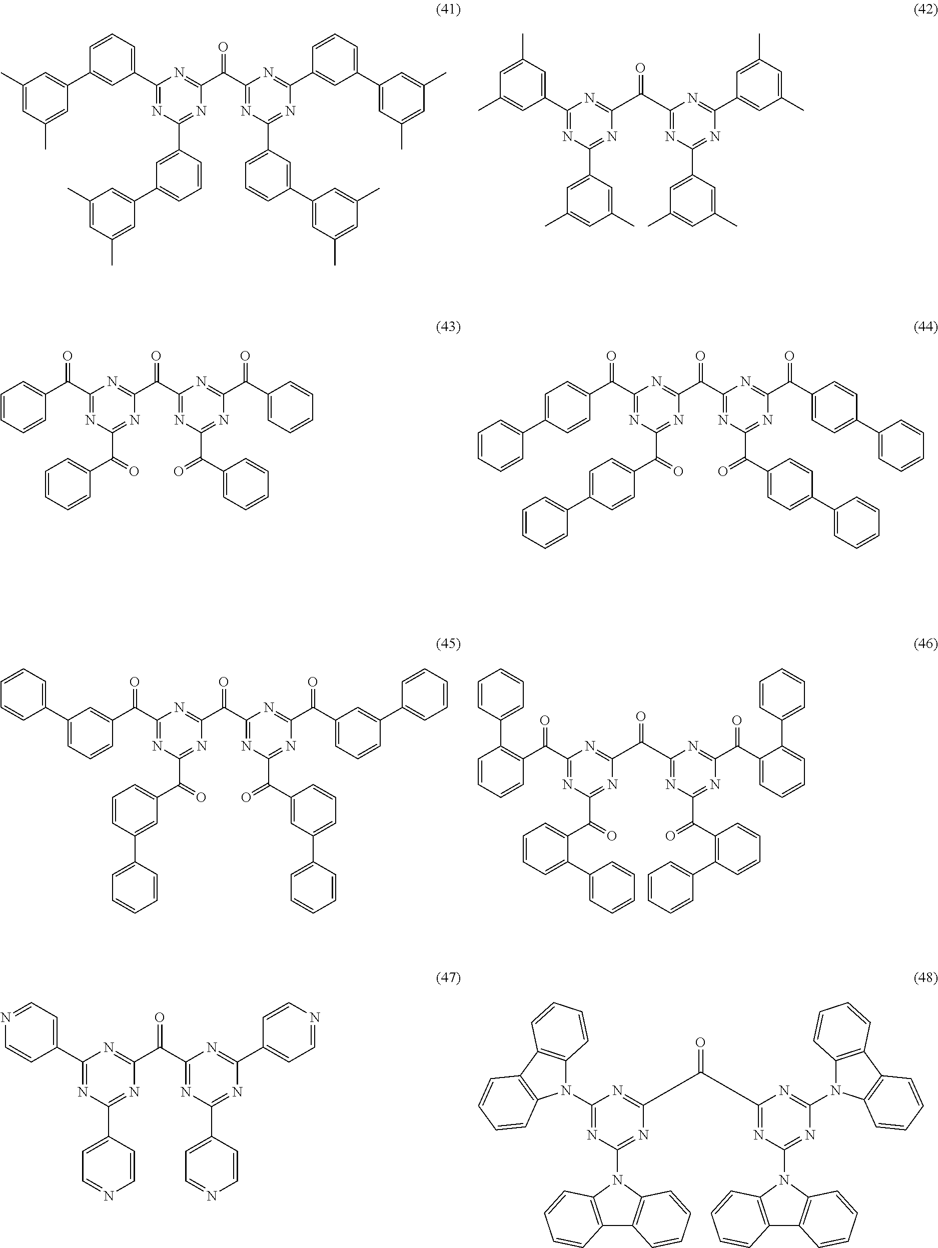

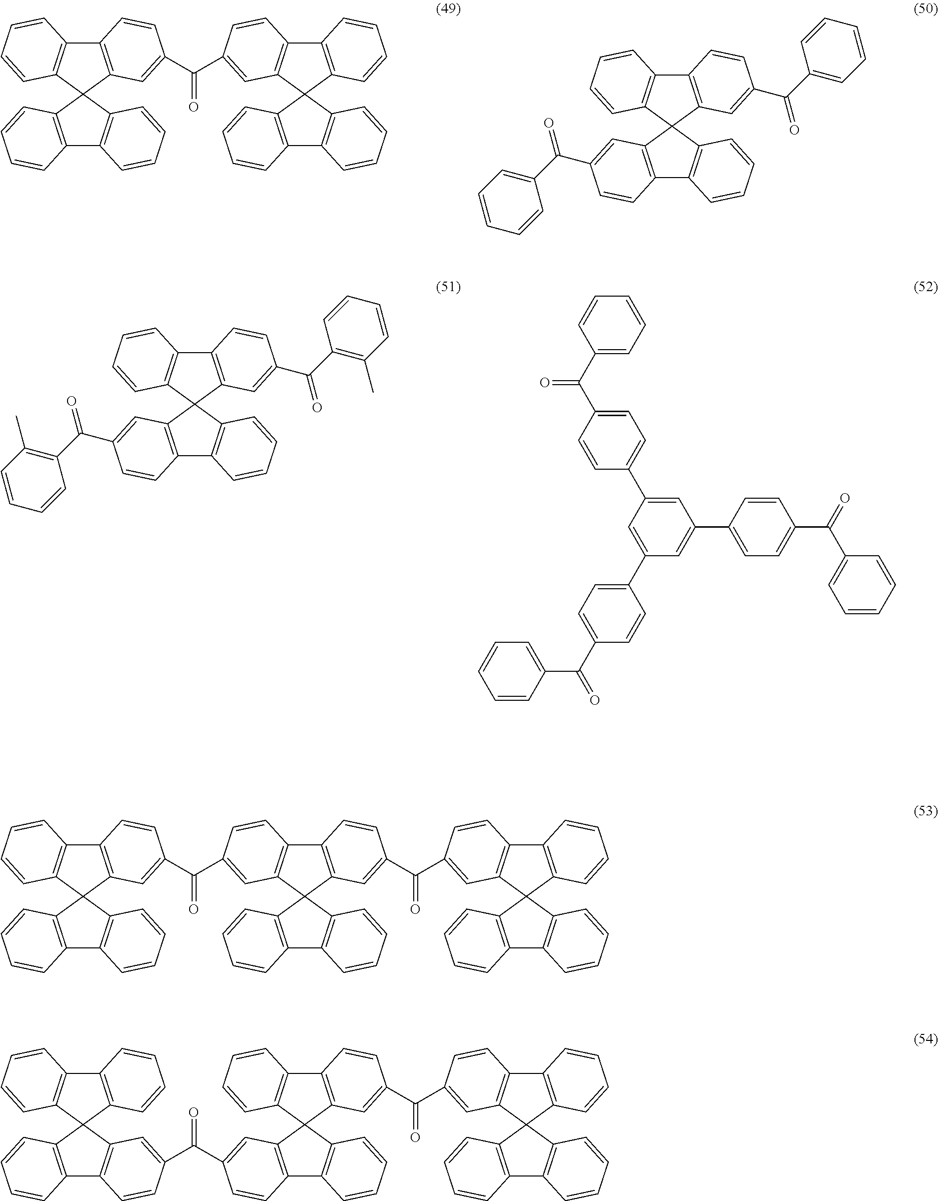

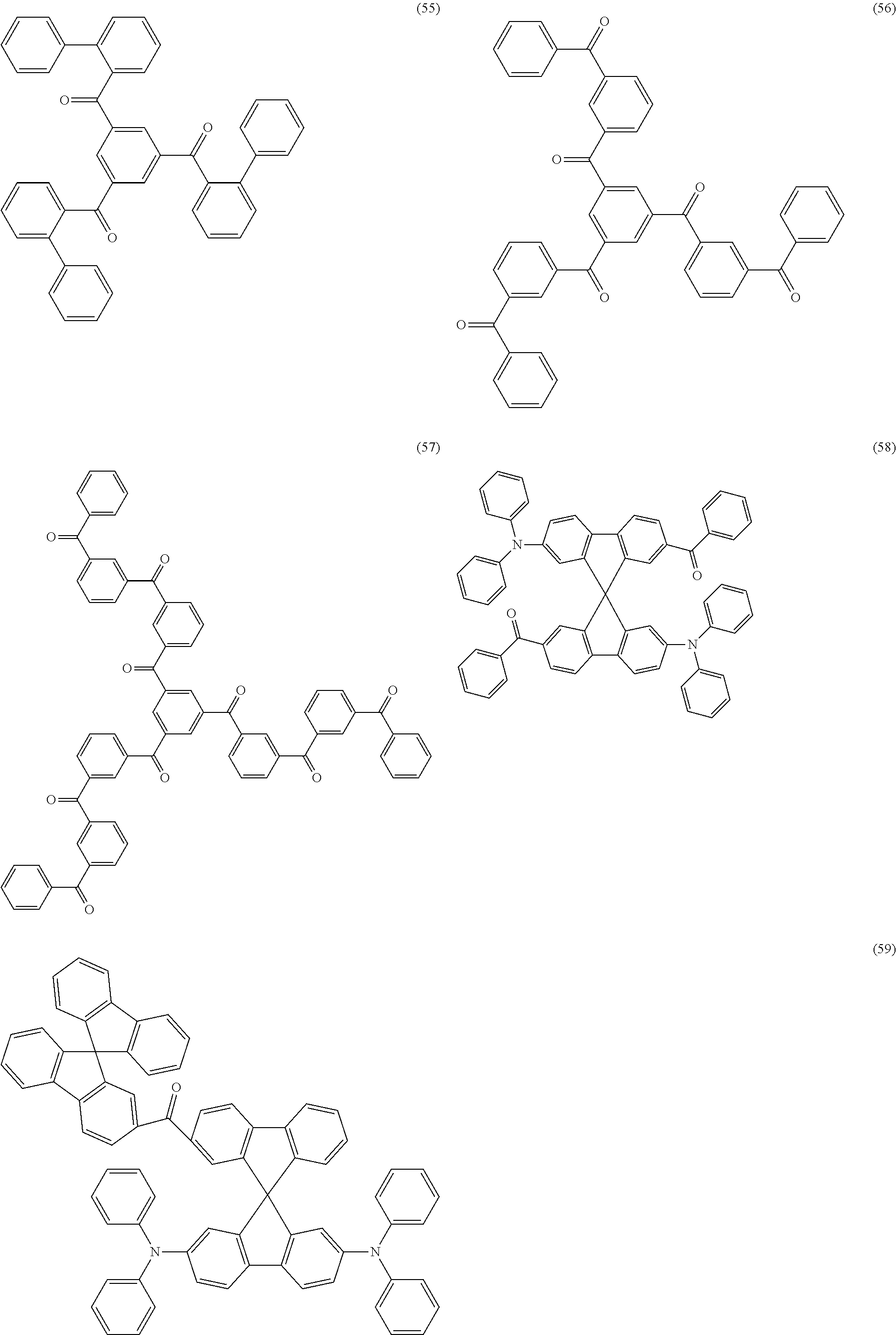

In a further preferred embodiment of the invention, the material for the electron-transport layer 1 is a triazine derivative, in particular a triazine derivative of the following formula (2) or (3):

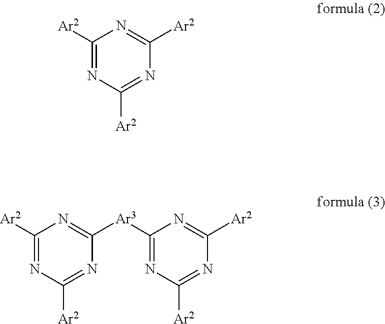

where R¹ has the meaning indicated above, and the following applies to the other symbols used:
Ar² is, identically or differently on each occurrence, a monovalent aromatic or heteroaromatic ring system having 5 to 60 aromatic ring atoms, which may in each case be substituted by one or more radicals R¹;
Ar³ is a divalent aromatic or heteroaromatic ring system having 5 to 60 aromatic ring atoms, which may be substituted by one or more radicals R¹.

In compounds of the formulae (2) and (3), at least one group Ar² is preferably selected from the groups of the following formulae (4) to (18):

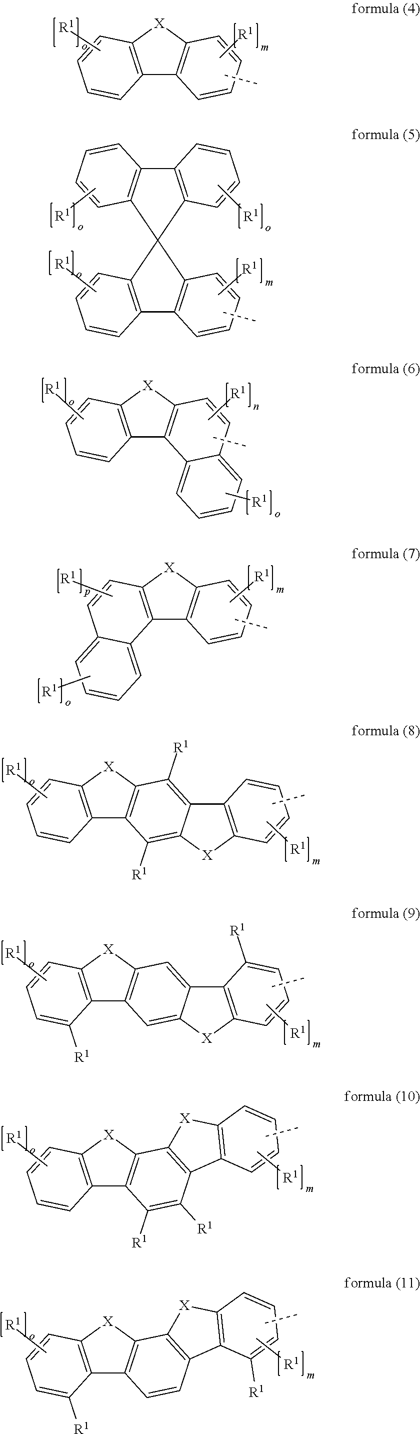

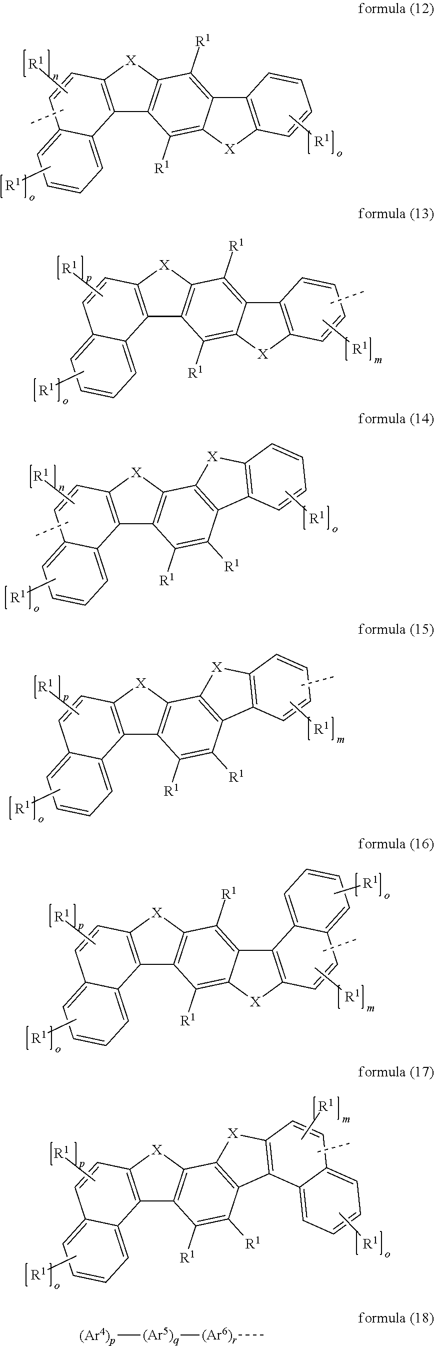

where R¹ has the same meaning as described above, the dashed bond represents the link to the triazine unit, and furthermore:
X is, identically or differently on each occurrence, a divalent bridge selected from B(R¹), C(R¹)₂, Si(R¹)₂, C═O, C═NR¹, C═C(R¹)₂, 0, S, S═O, SO₂, N(R¹), P(R¹) and P(═O)R¹;
m is on each occurrence, identically or differently, 0, 1, 2 or 3;
o is on each occurrence, identically or differently, 0, 1, 2, 3 or 4;
Ar⁴, Ar⁶ are, identically or differently on each occurrence, an aryl or heteroaryl group having 5 to 18 aromatic ring atoms, which may be substituted by one or more radicals R¹;
Ar⁵ is a condensed aryl or heteroaryl group having 10 to 18 aromatic ring atoms, which may be substituted by one or more radicals R¹;
p, r are, identically or differently on each occurrence, 0, 1 or 2, preferably 0 or 1;
q is 1 or 2, preferably 1.

In a preferred embodiment of the invention, Ar⁵ in formula (18) is a condensed aryl group having 10 to 18 aromatic C atoms, which may be substituted by one or more radicals R¹. Ar⁵ is particularly preferably selected from the group consisting of naphthalene, anthracene, phenanthrene, pyrene, benzanthracene and chrysene, each of which may be substituted by one or more radicals R¹. Anthracene and benzanthracene are very particularly preferred.

In a further preferred embodiment of the invention, the groups Ar⁴ and Ar⁶ in formula (18) are, identically or differently on each occurrence, an aryl or heteroaryl group having 6 to 14 aromatic ring atoms, which may in each case be substituted by one or more radicals R¹. Ar⁴ and Ar⁶ are particularly preferably selected, identically or differently on each occurrence, from the group consisting of benzene, pyridine, pyrazine, pyridazine, pyrimidine, triazine, naphthalene, quinoline, isoquinoline, anthracene, phenanthrene, phenanthroline, pyrene, benzanthracene and chrysene, each of which may be substituted by one or more radicals R¹. Benzene and naphthalene are very particularly preferred.

Particularly preferred groups Ar² are selected from the groups of the following formulae (4a) to (17a):

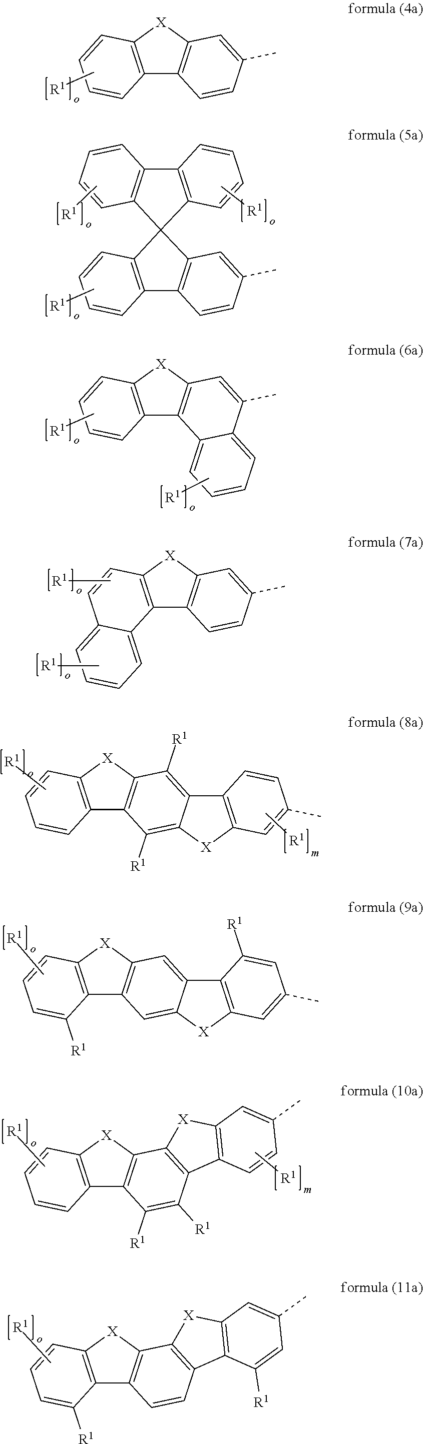

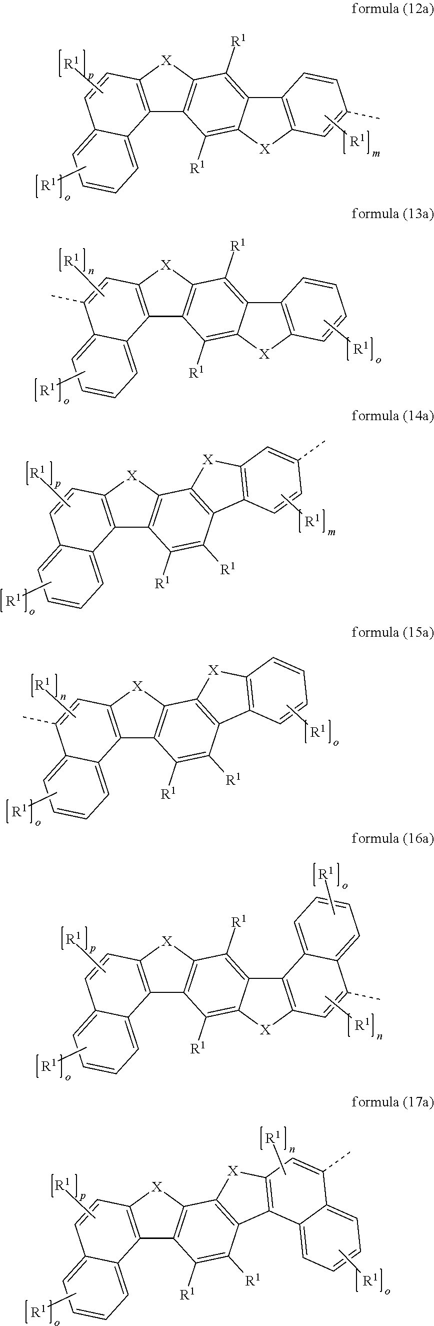

where the symbols and indices used have the same meaning as described above. X here is preferably selected, identically or differently, from C(R¹)₂, N(R¹), O and S, particularly preferably C(R¹)₂.

Preferred groups Ar³ in compounds of the formula (3) are selected from the groups of the following formulae (19) to (30):

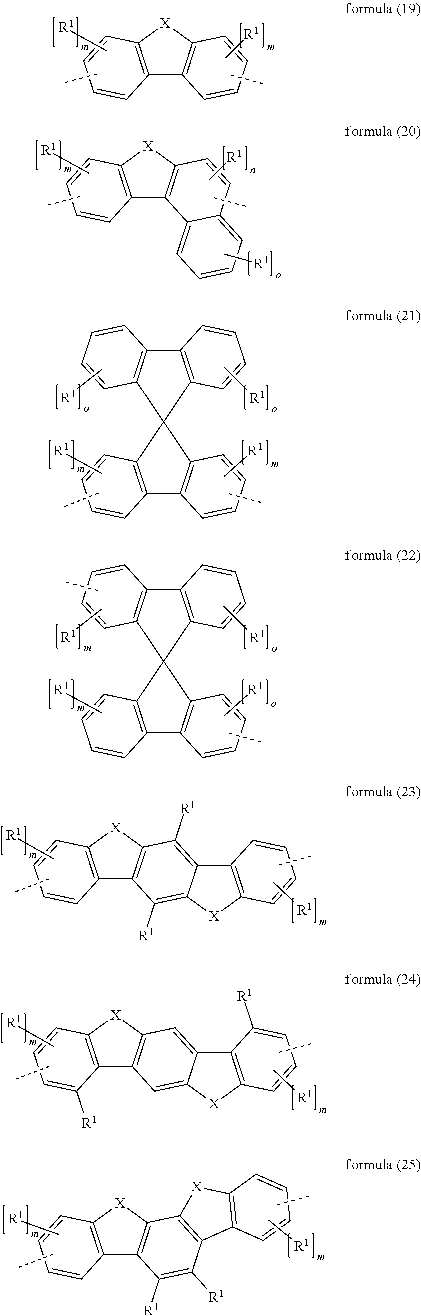

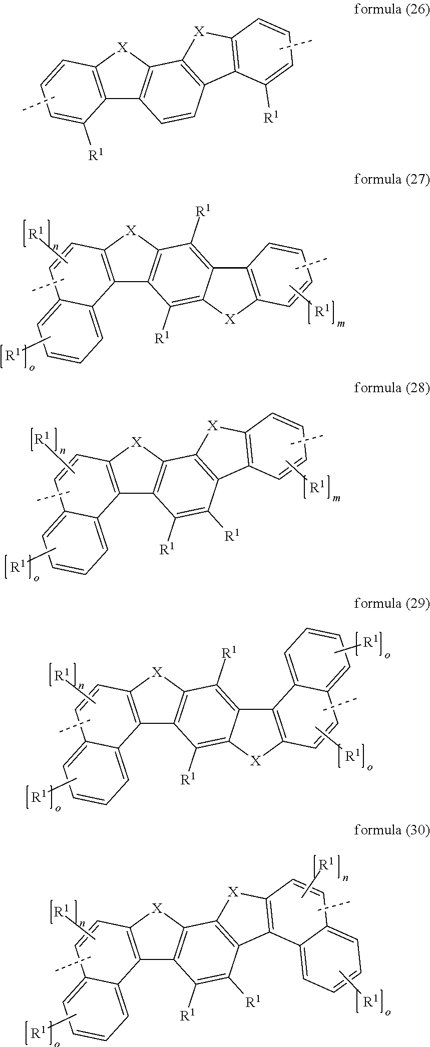

where the symbols and indices used have the same meaning as described above, and the dashed bond represents the link to the two triazine units.

Particularly preferred groups Ar³ are selected from the groups of the following formulae (19a) to (30a):

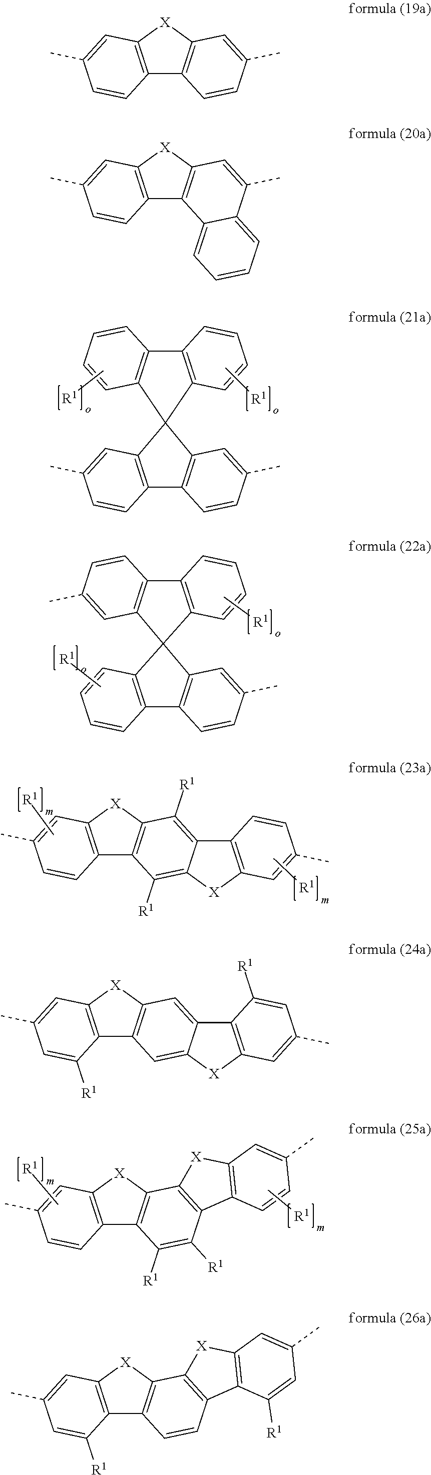

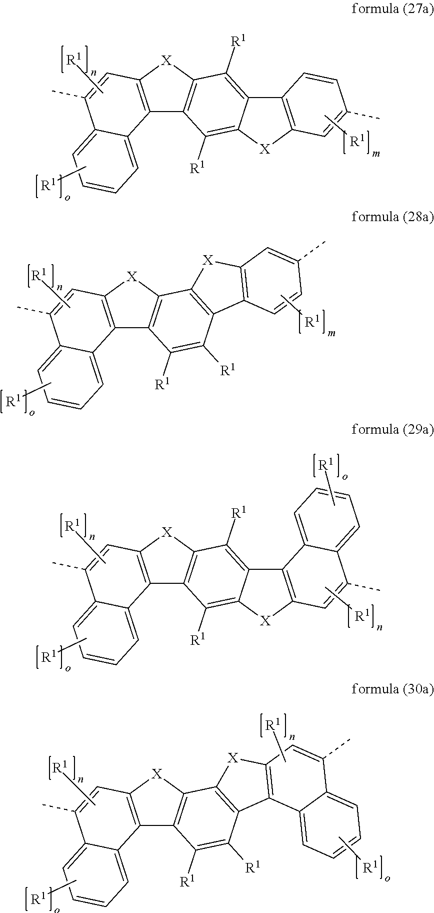

where the symbols and indices used have the same meaning as described above. X here is preferably selected, identically or differently, from C(R¹)₂, N(R¹), O and S, particularly preferably C(R¹)₂.

Preference is furthermore given to compounds of the formula (3) given above in which the group Ar³ is selected from the formulae (19) to (30) given above and Ar² is selected, identically or differently on each occurrence, from the formulae (4) to (18) given above or phenyl, 1- or 2-naphthyl, ortho-, meta- or para-biphenyl, each of which may be substituted by one or more radicals R¹, but are preferably unsubstituted.

Examples of preferred compounds of the formulae (2) and (3) are structures (1) to (178) depicted below:

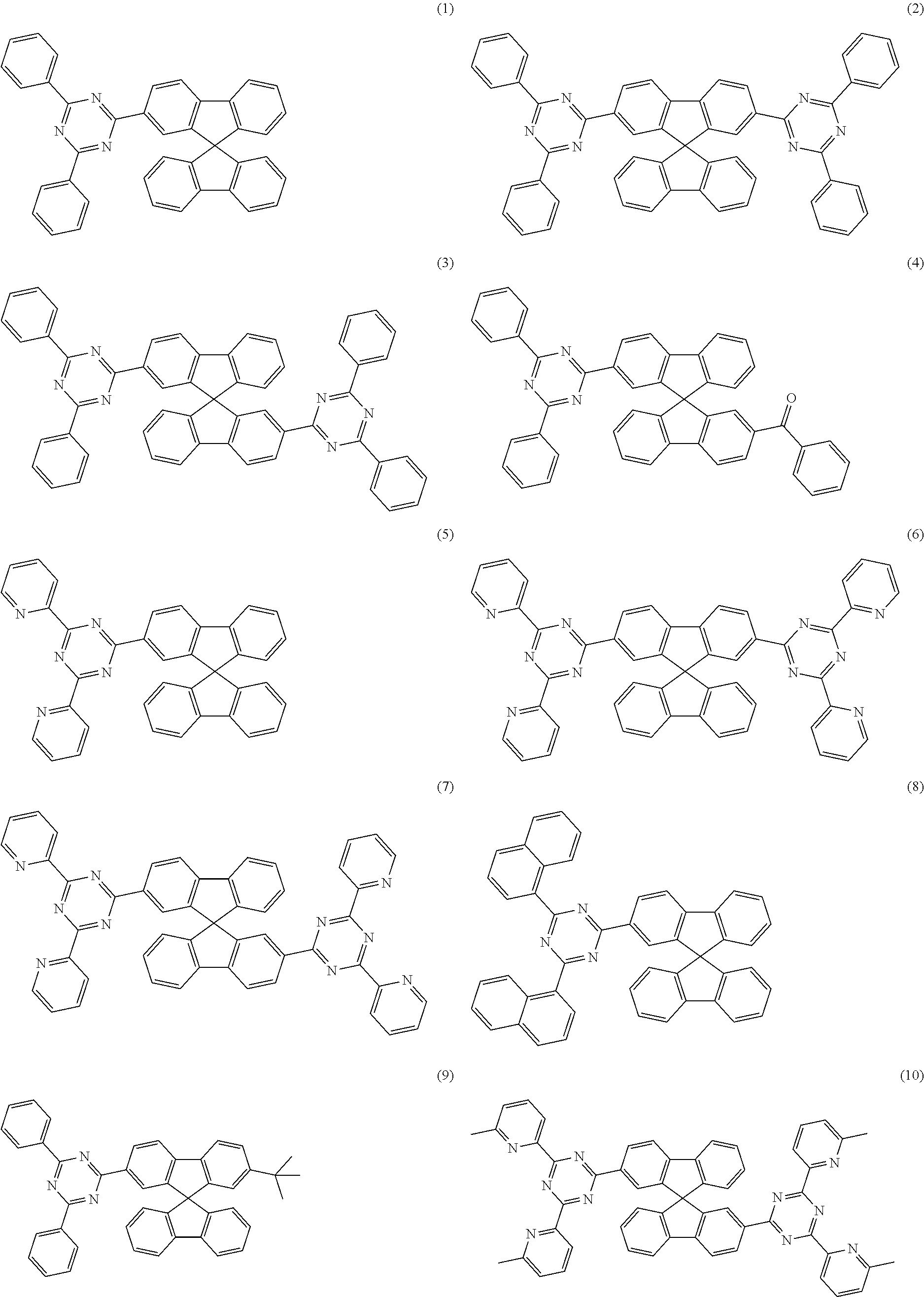

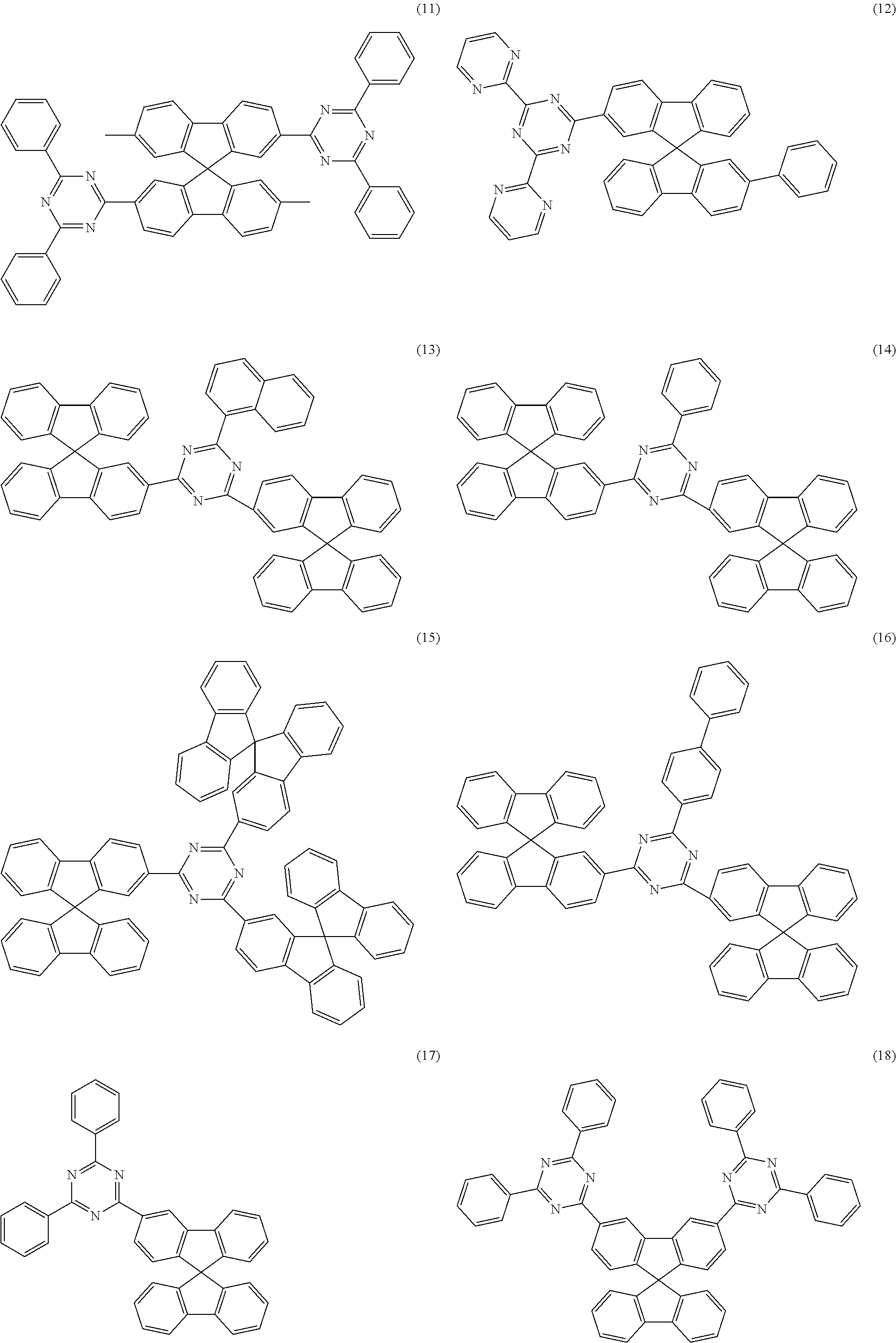

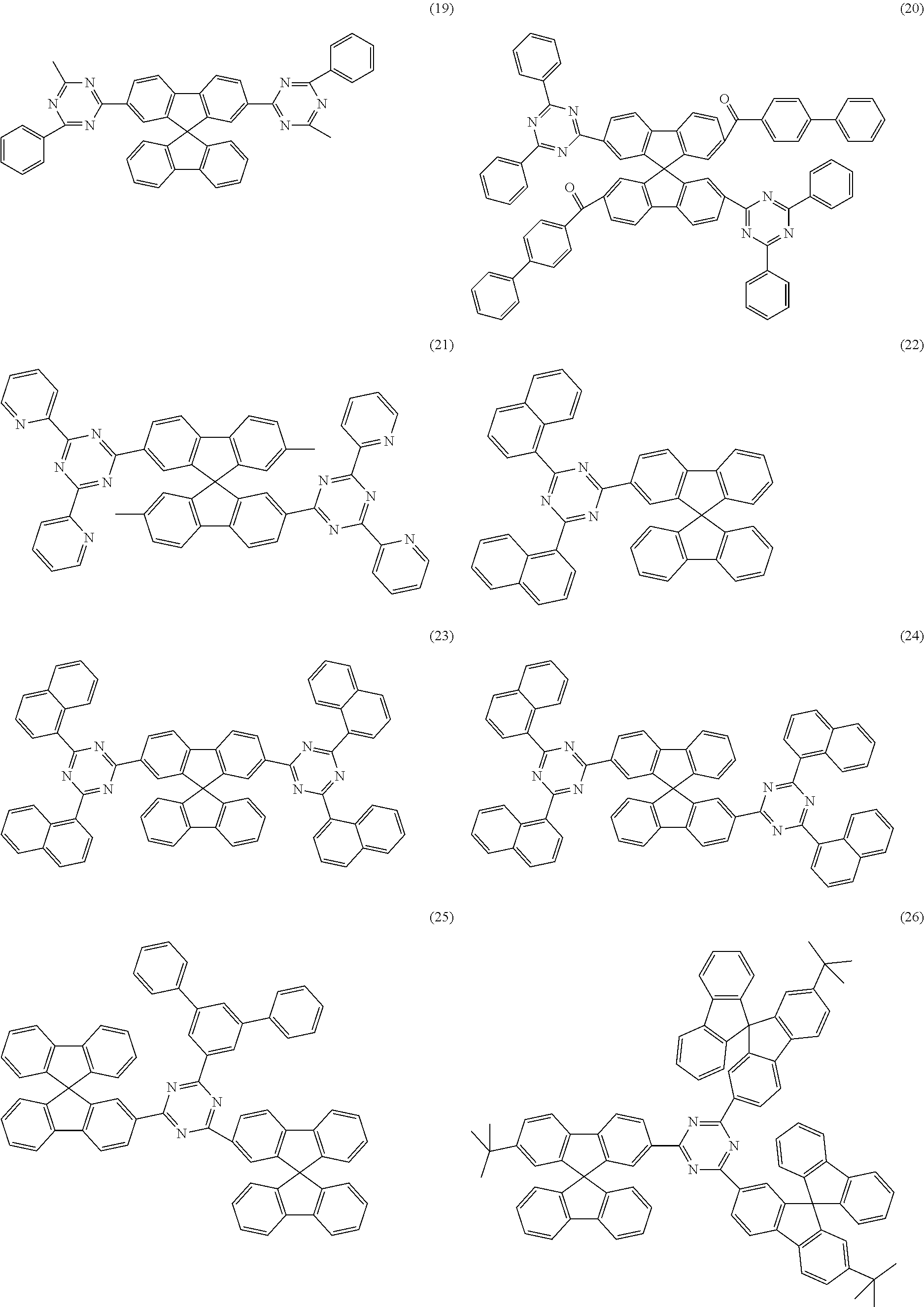

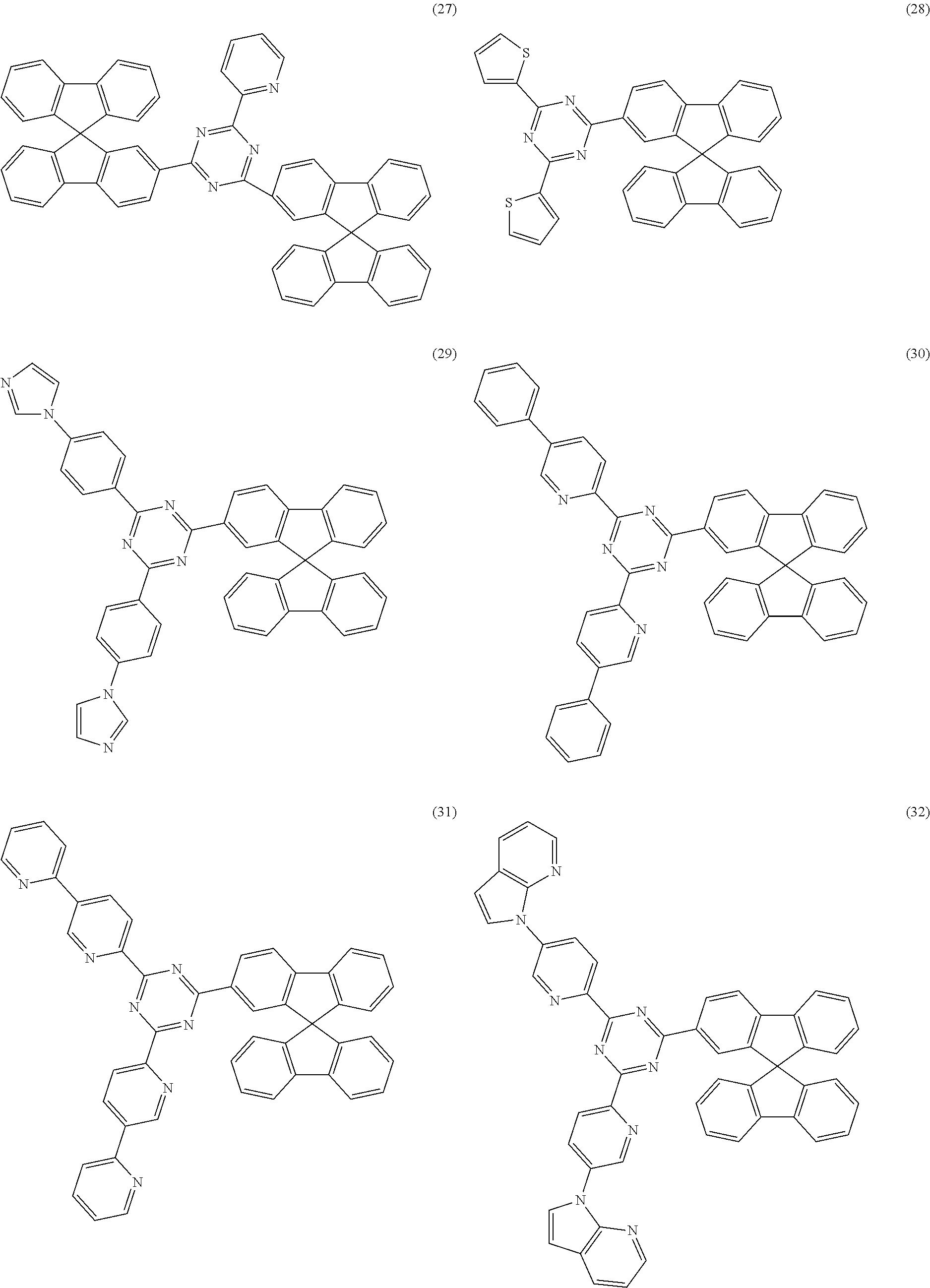

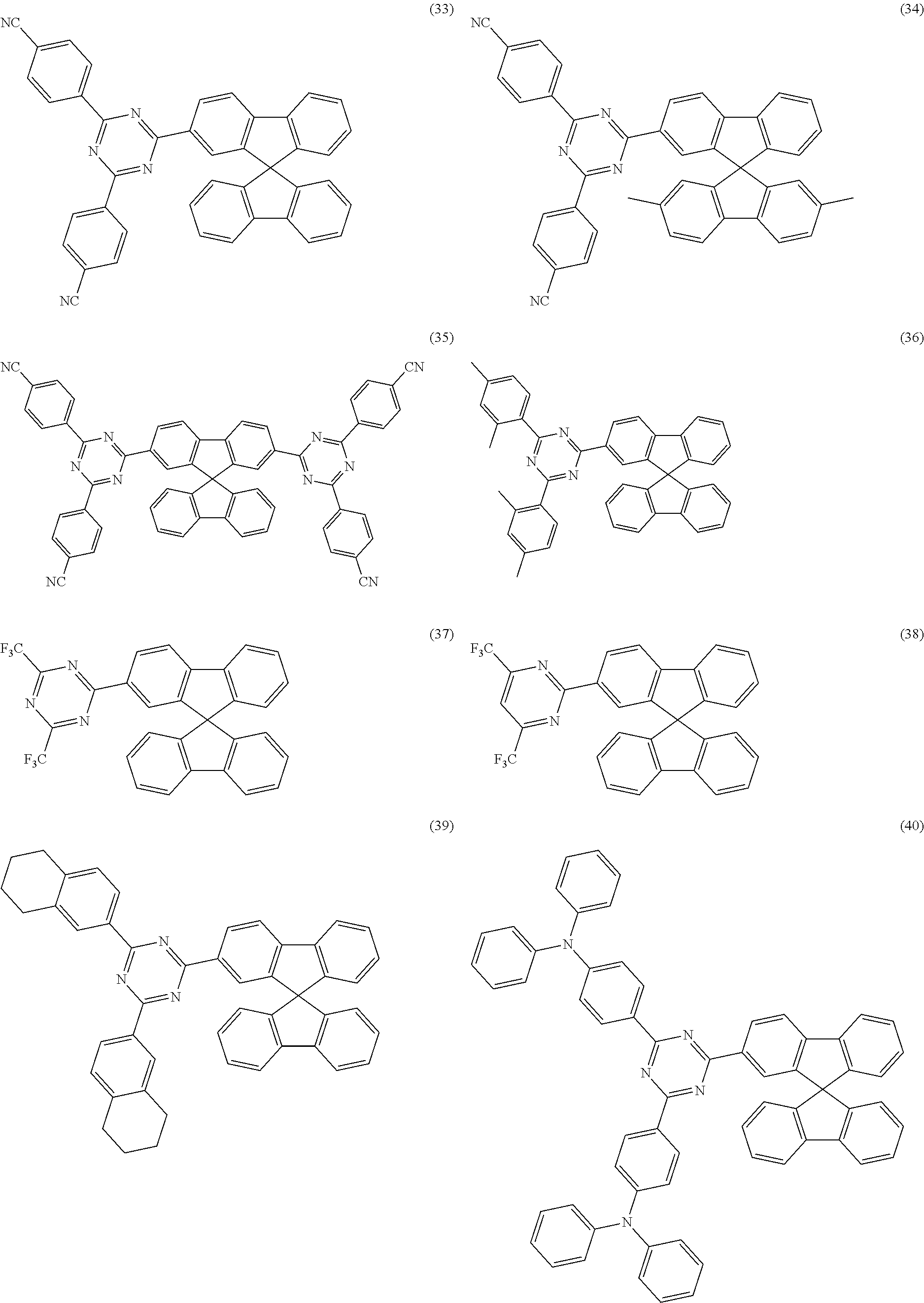

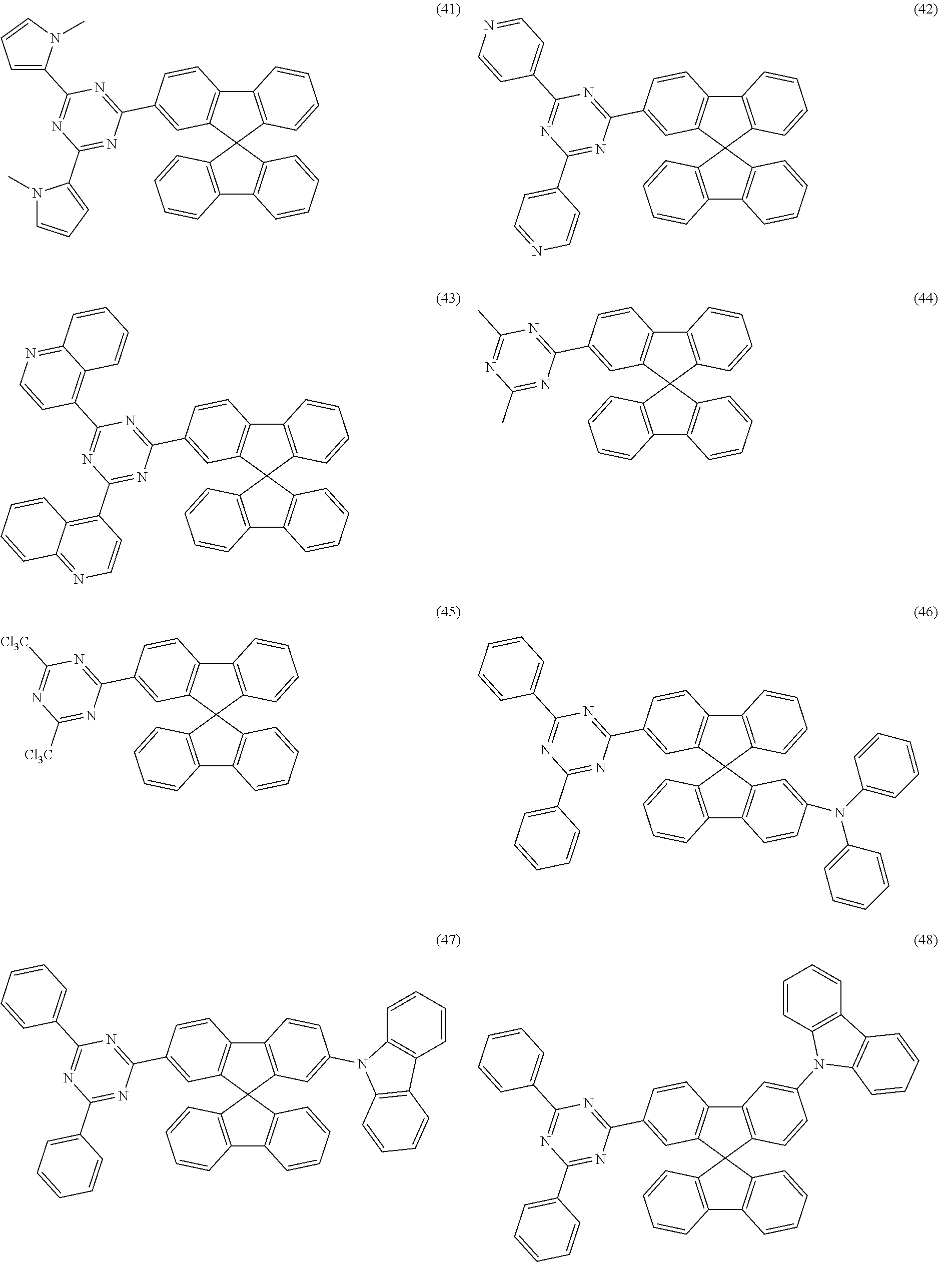

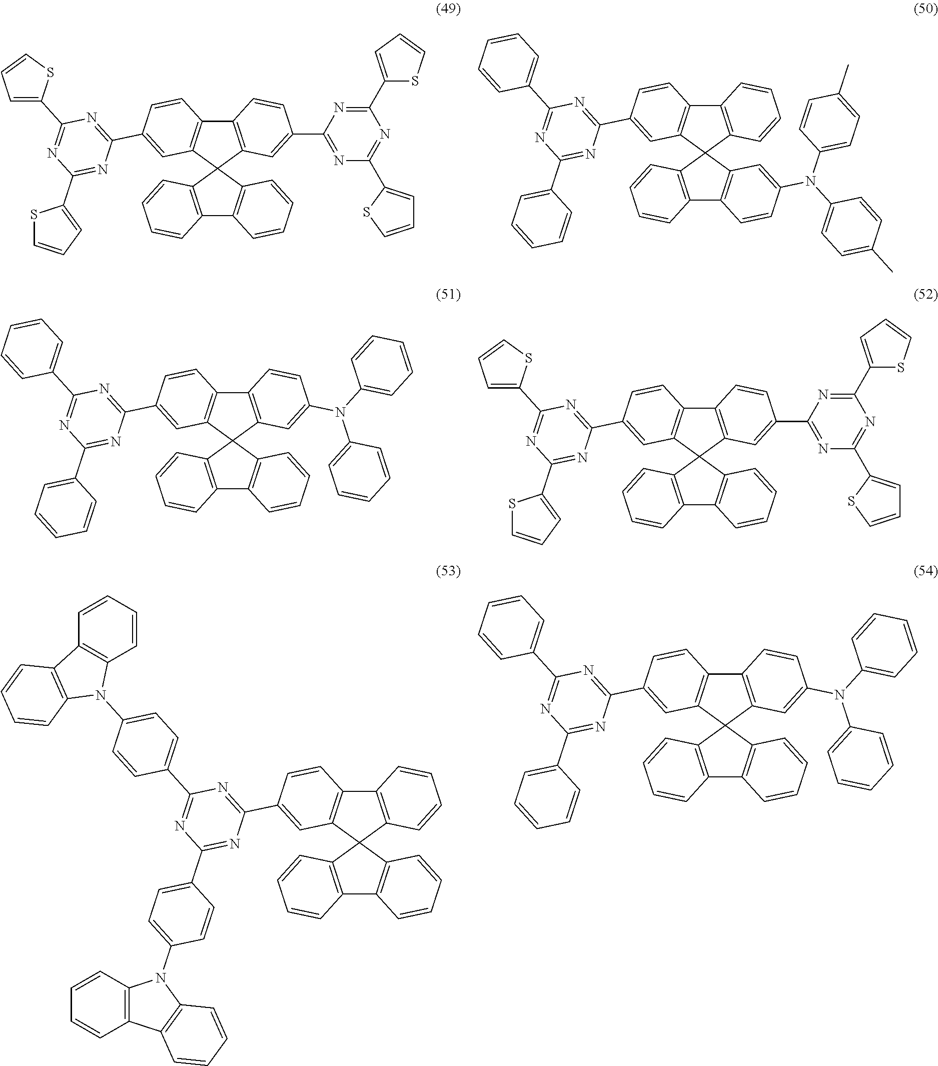

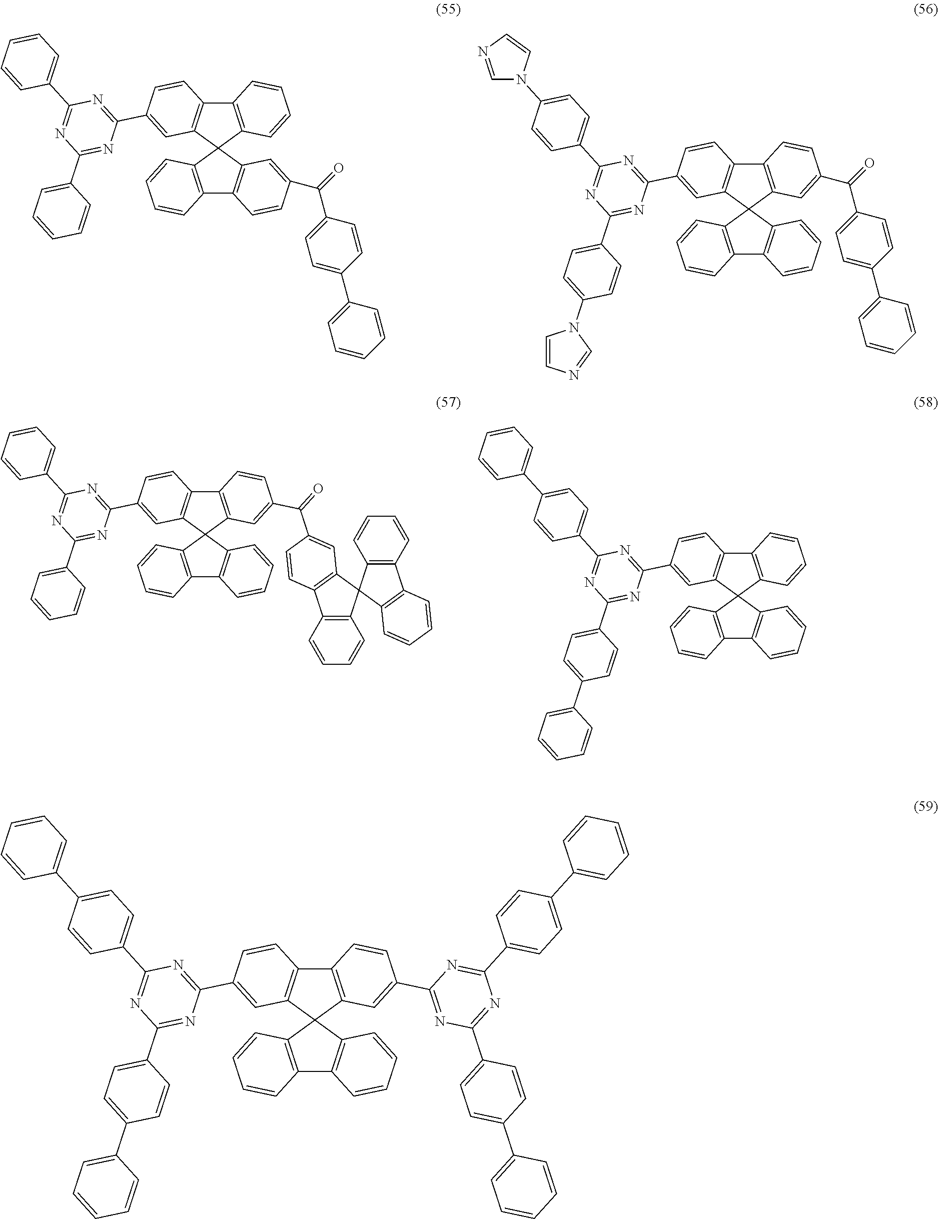

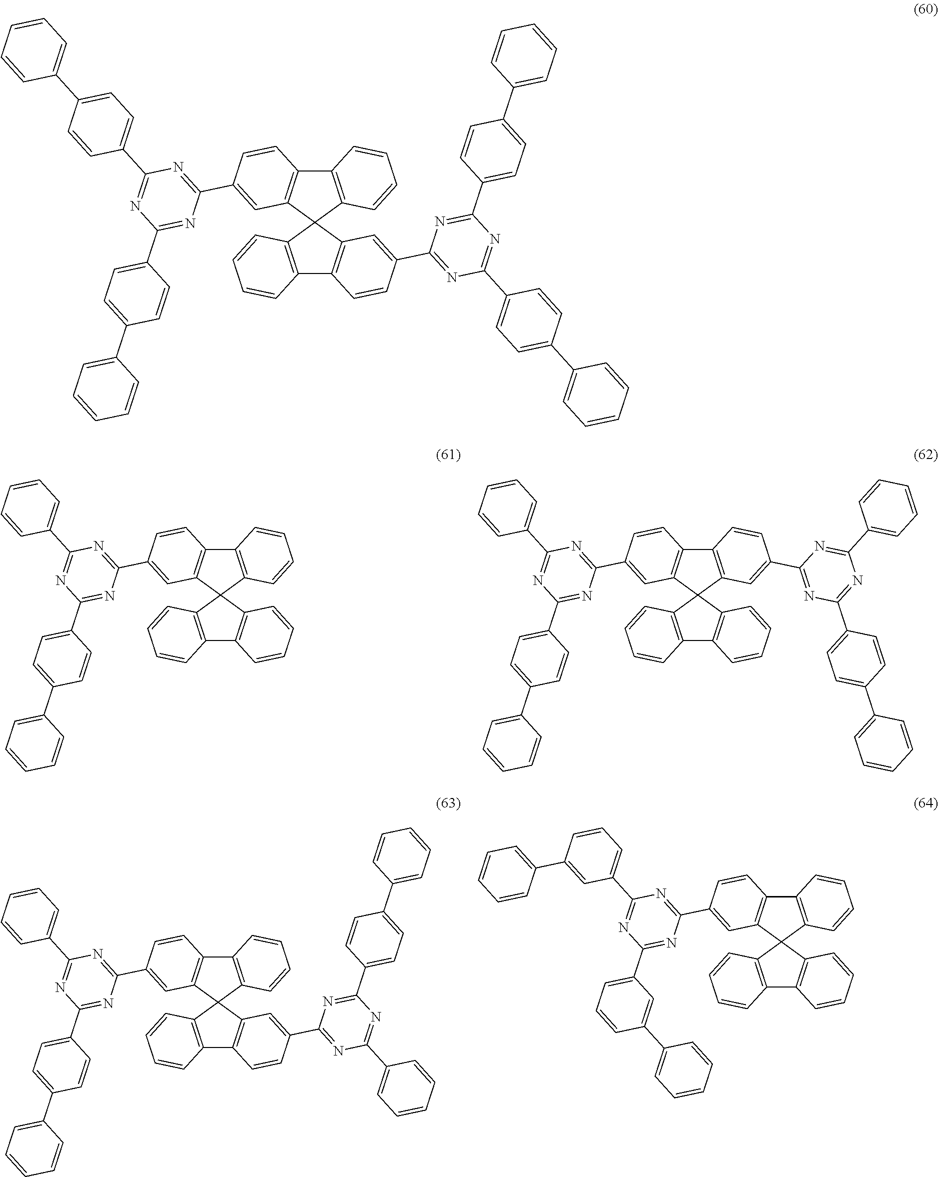

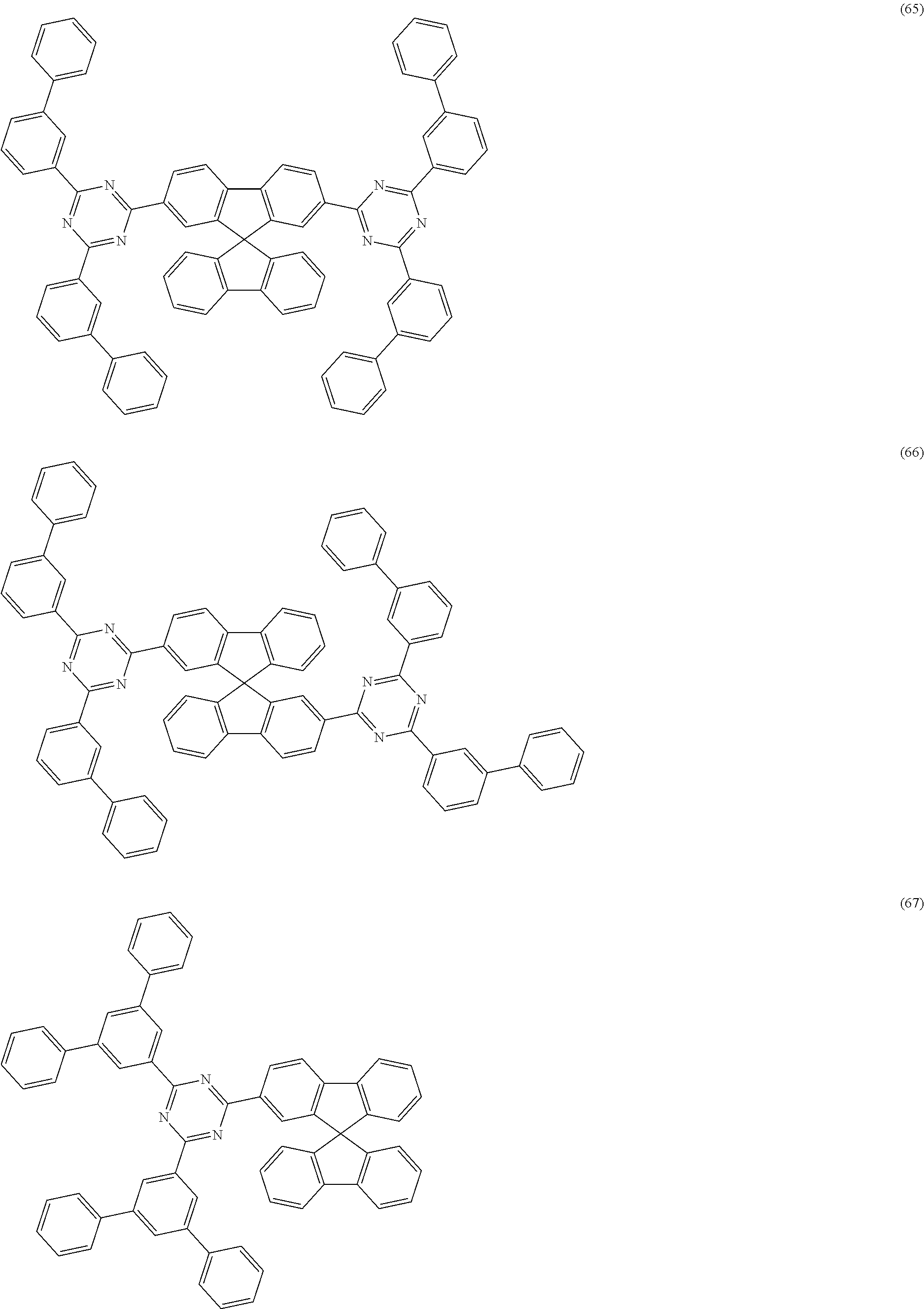 [SMILES: c1ccc(-c2cccc(-c3nc(-c4cccc(-c5ccccc5)c4)nc(-c4ccc5c(c4)C4(c6ccccc6-c6ccccc64)c4cc(-c6nc(-c7cccc(-c8ccccc8)c7)nc(-c7cccc(-c8ccccc8)c7)n6)ccc4-5)n3)c2)cc1 ; c1ccc(-c2cccc(-c3nc(-c4cccc(-c5ccccc5)c4)nc(-c4ccc5c(c4)C4(c6ccccc6-5)c5ccccc5-c5ccc(-c6nc(-c7cccc(-c8ccccc8)c7)nc(-c7cccc(-c8ccccc8)c7)n6)cc54)n3)c2)cc1 ; c1ccc(-c2cc(-c3ccccc3)cc(-c3nc(-c4cc(-c5ccccc5)cc(-c5ccccc5)c4)nc(-c4ccc5c(c4)C4(c6ccccc6-c6ccccc64)c4ccccc4-5)n3)c2)cc1]

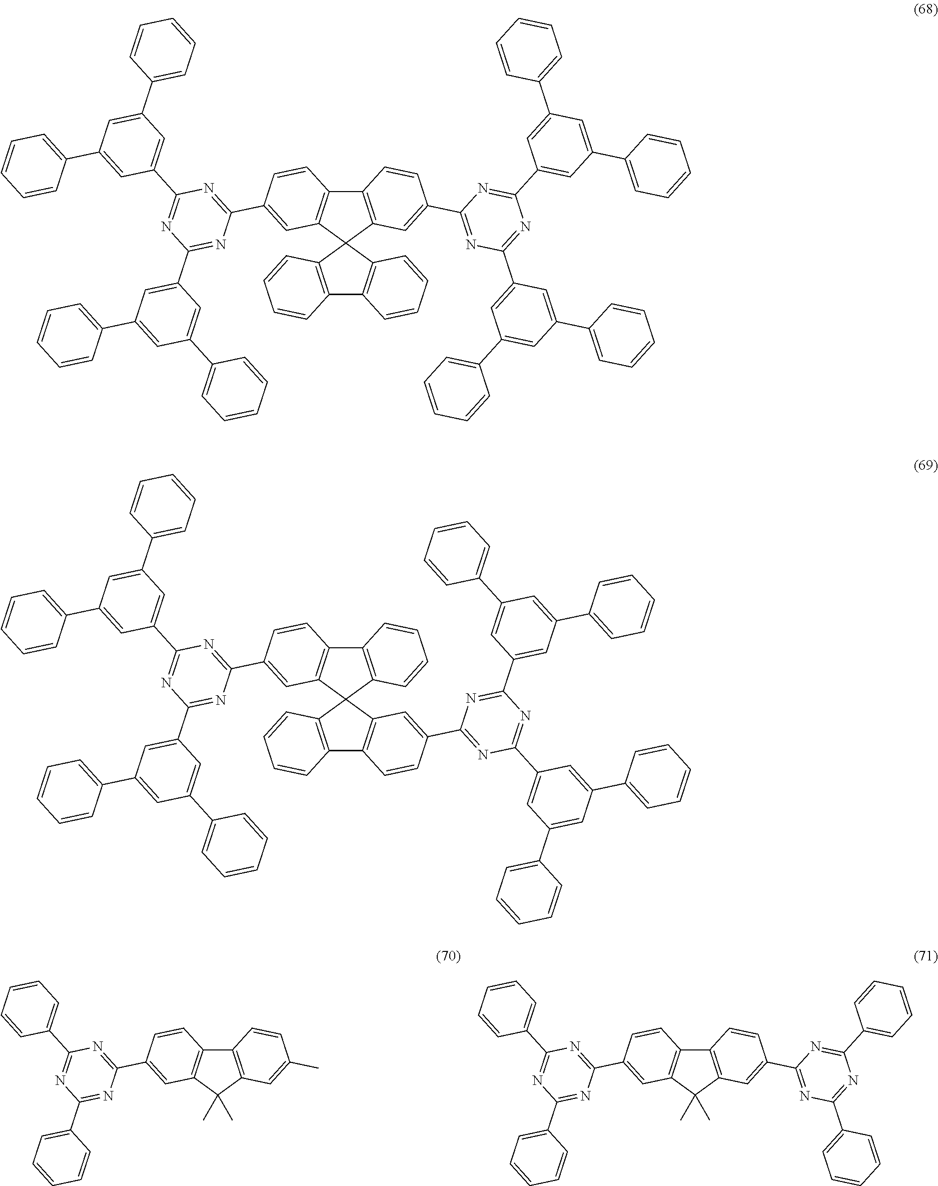

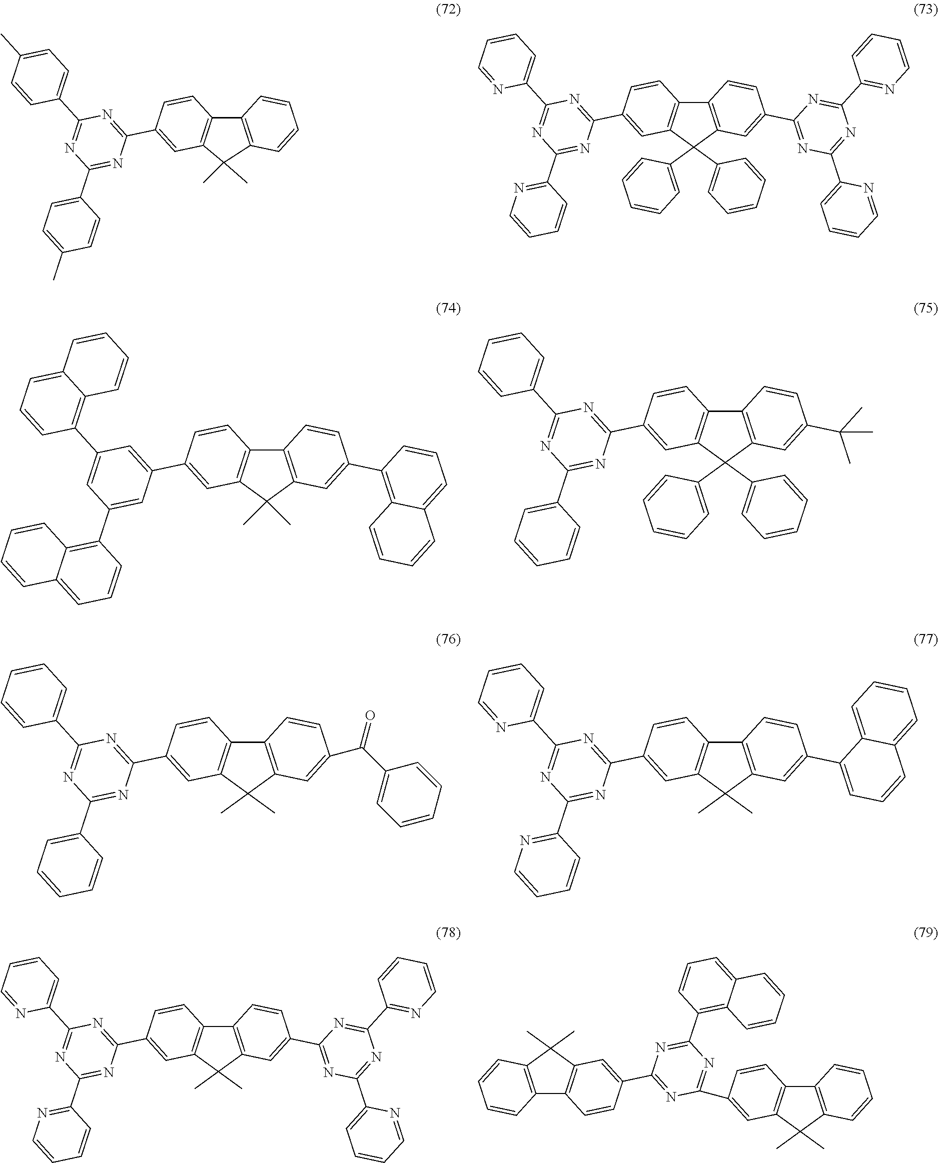

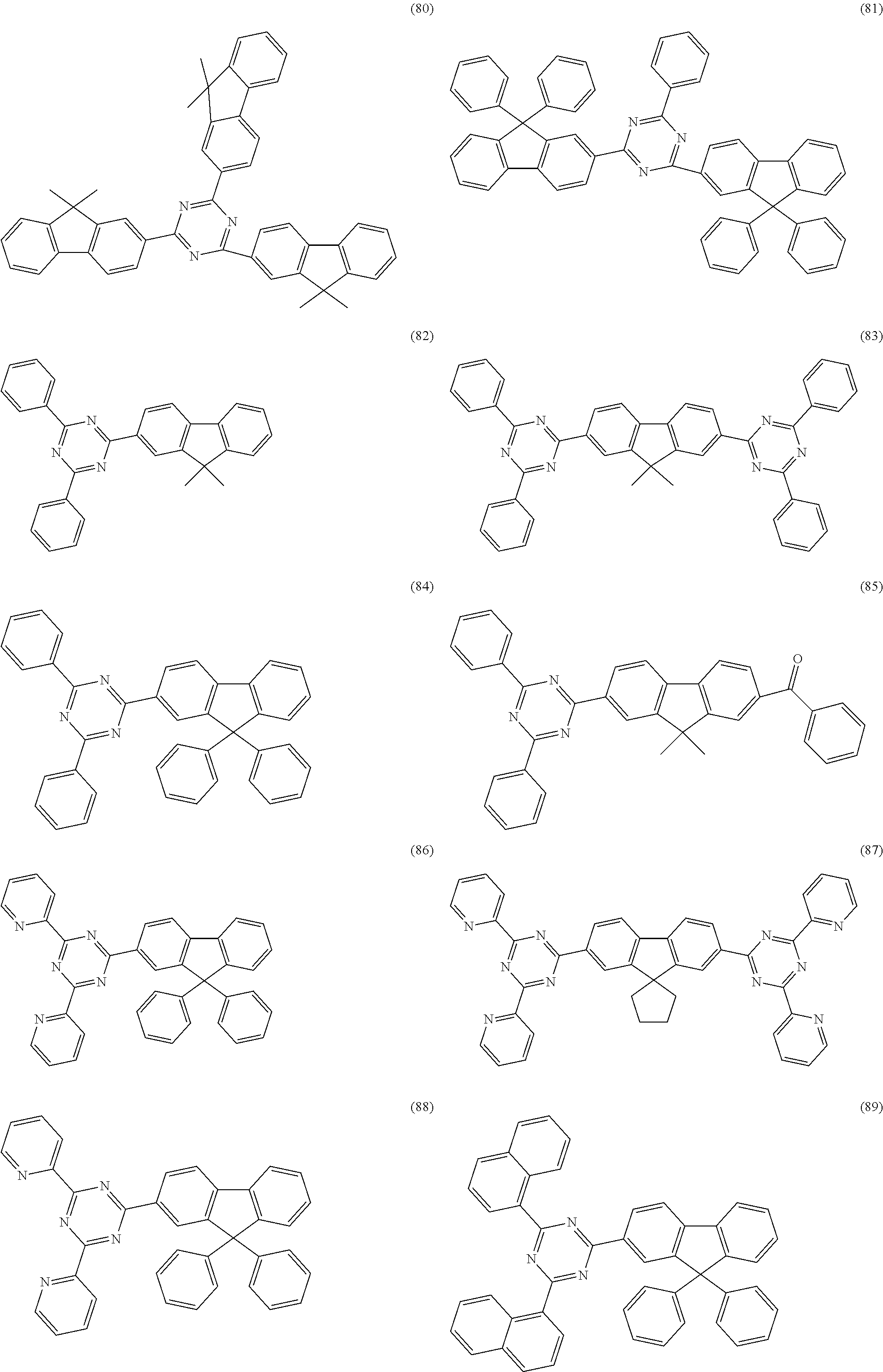

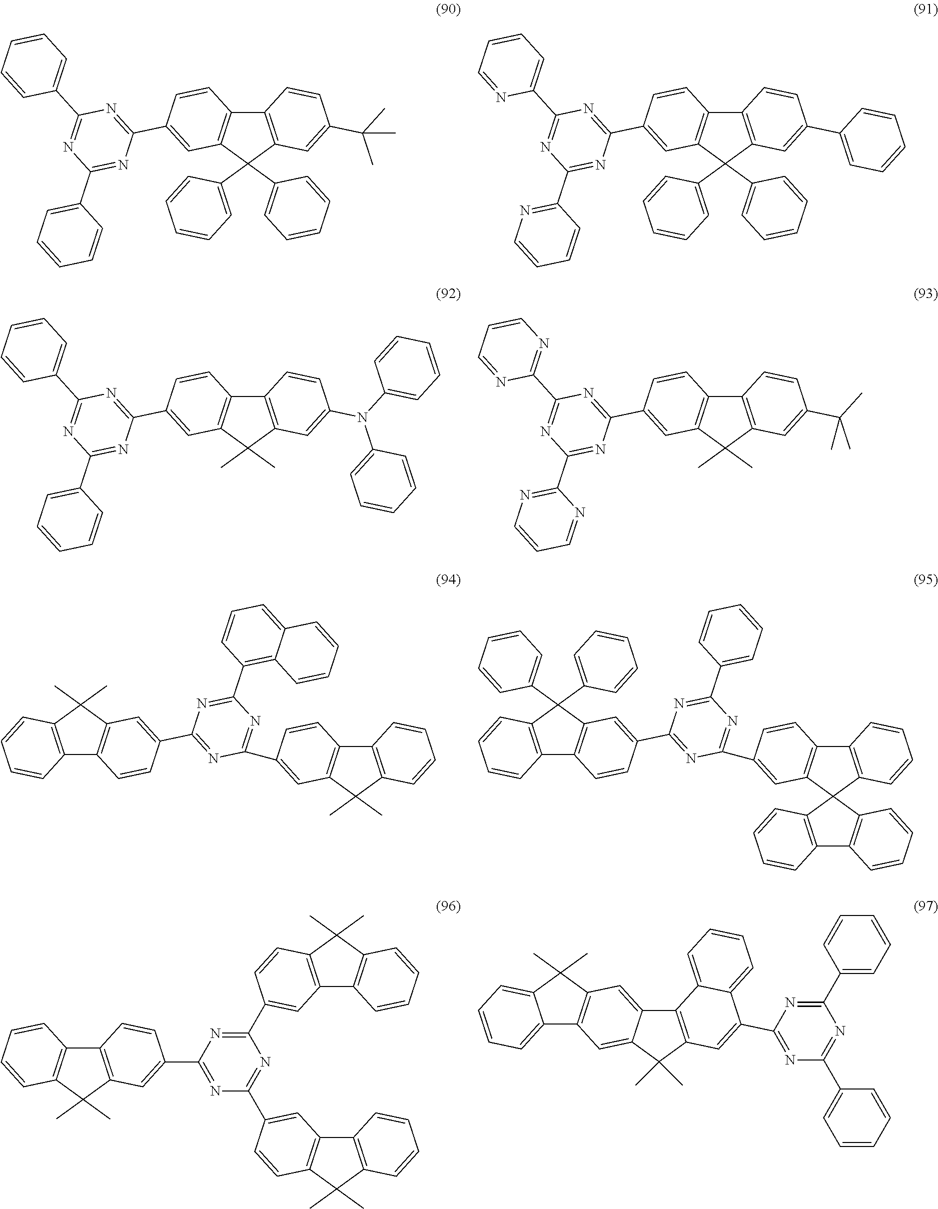

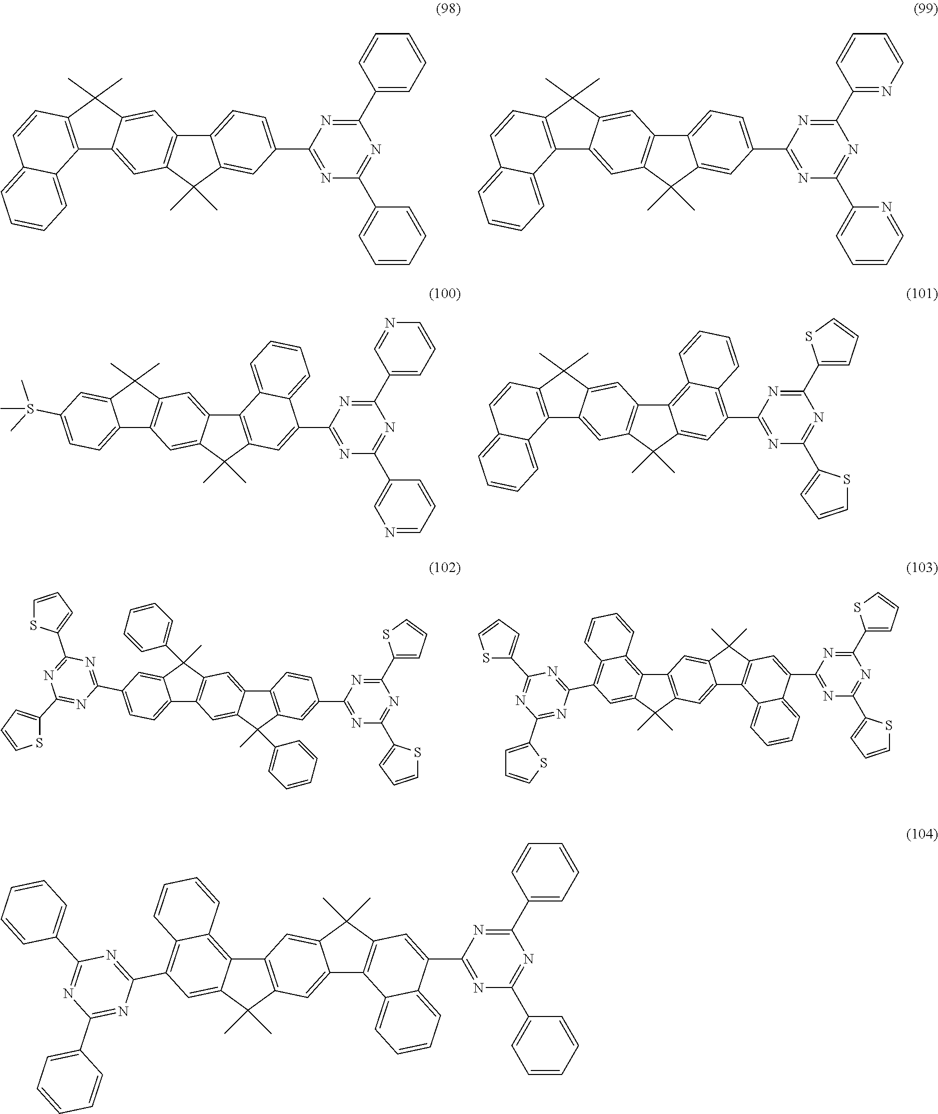

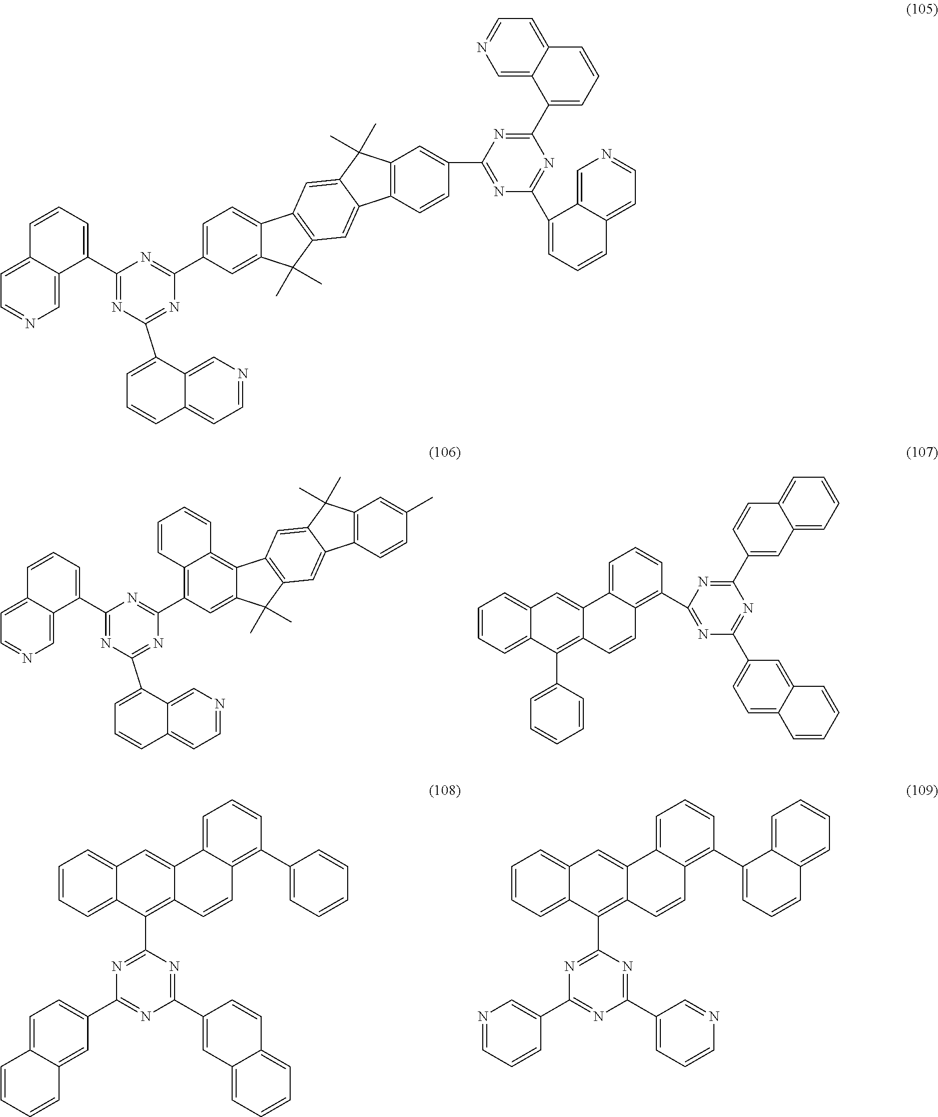 [SMILES: CC1(C)c2cc(-c3nc(-c4cccc5ccncc45)nc(-c4cccc5ccncc45)n3)ccc2-c2cc3c(cc21)-c1ccc(-c2nc(-c4cccc5ccncc45)nc(-c4cccc5ccncc45)n2)cc1C3(C)C ; Cc1ccc2c(c1)C(C)(C)c1cc3c(cc1-2)C(C)(C)c1cc(-c2nc(-c4cccc5ccncc45)nc(-c4cccc5ccncc45)n2)c2ccccc2c1-3 ; c1ccc(-c2c3ccccc3cc3c2ccc2c(-c4nc(-c5ccc6ccccc6c5)nc(-c5ccc6ccccc6c5)n4)cccc23)cc1 ; c1ccc(-c2cccc3c2ccc2c(-c4nc(-c5ccc6ccccc6c5)nc(-c5ccc6ccccc6c5)n4)c4ccccc4cc23)cc1 ; c1cncc(-c2nc(-c3cccnc3)nc(-c3c4ccccc4cc4c3ccc3c(-c5cccc6ccccc56)cccc34)n2)c1]

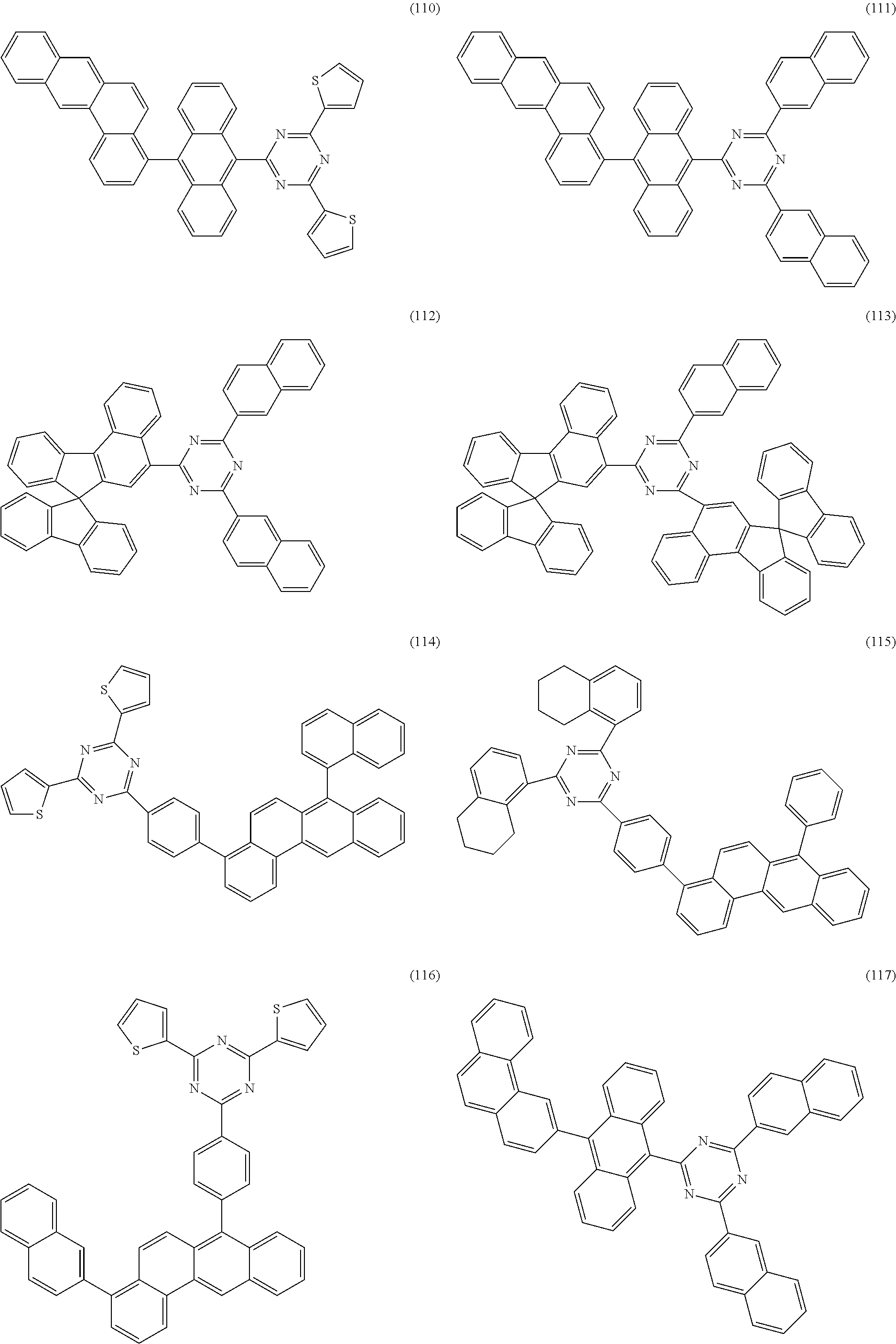

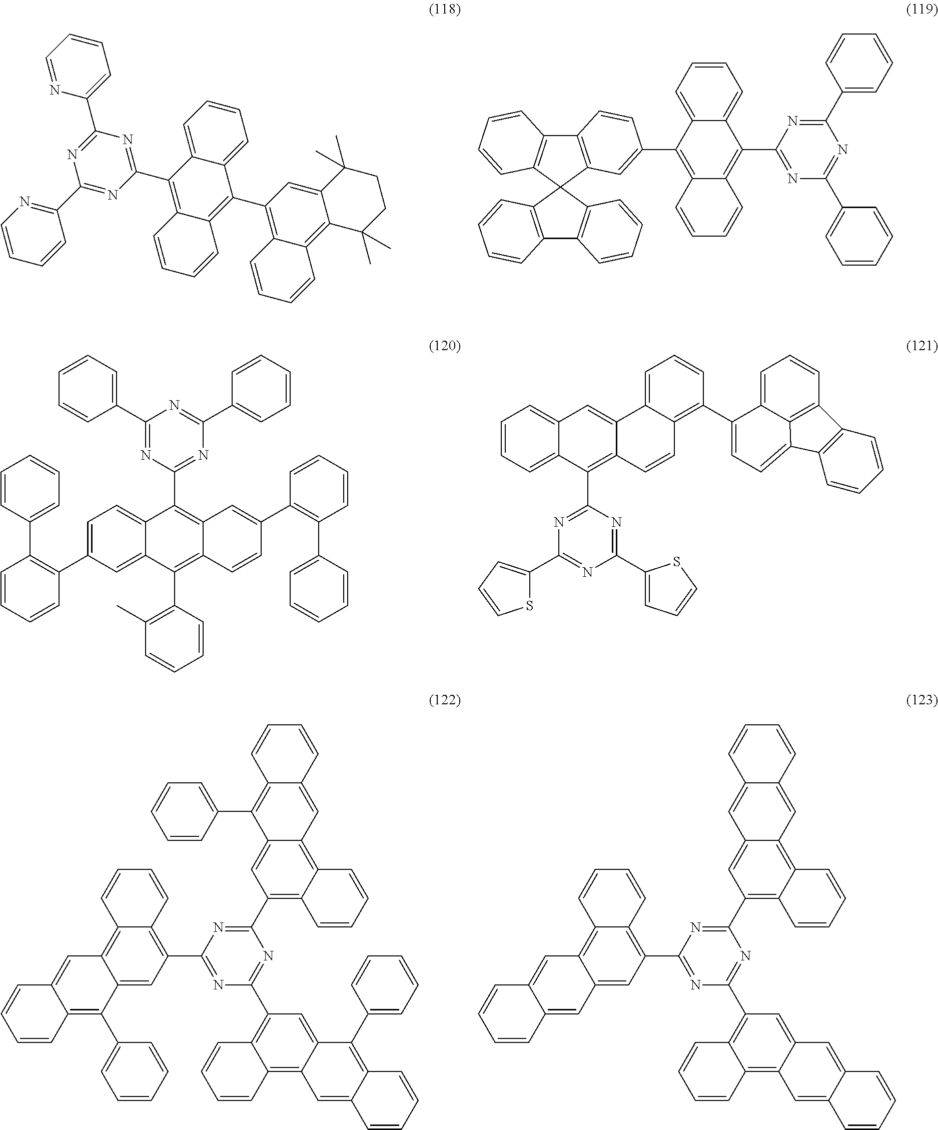

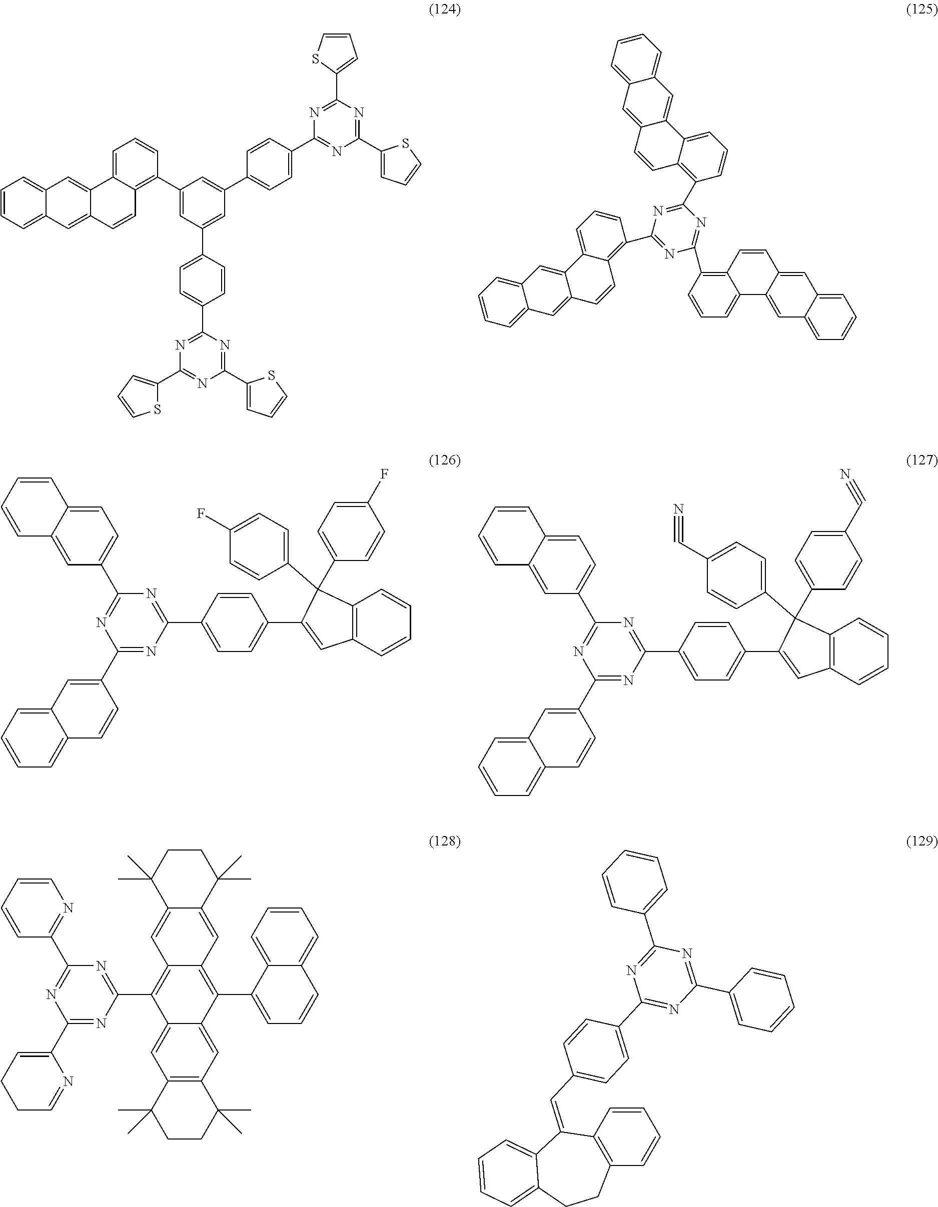

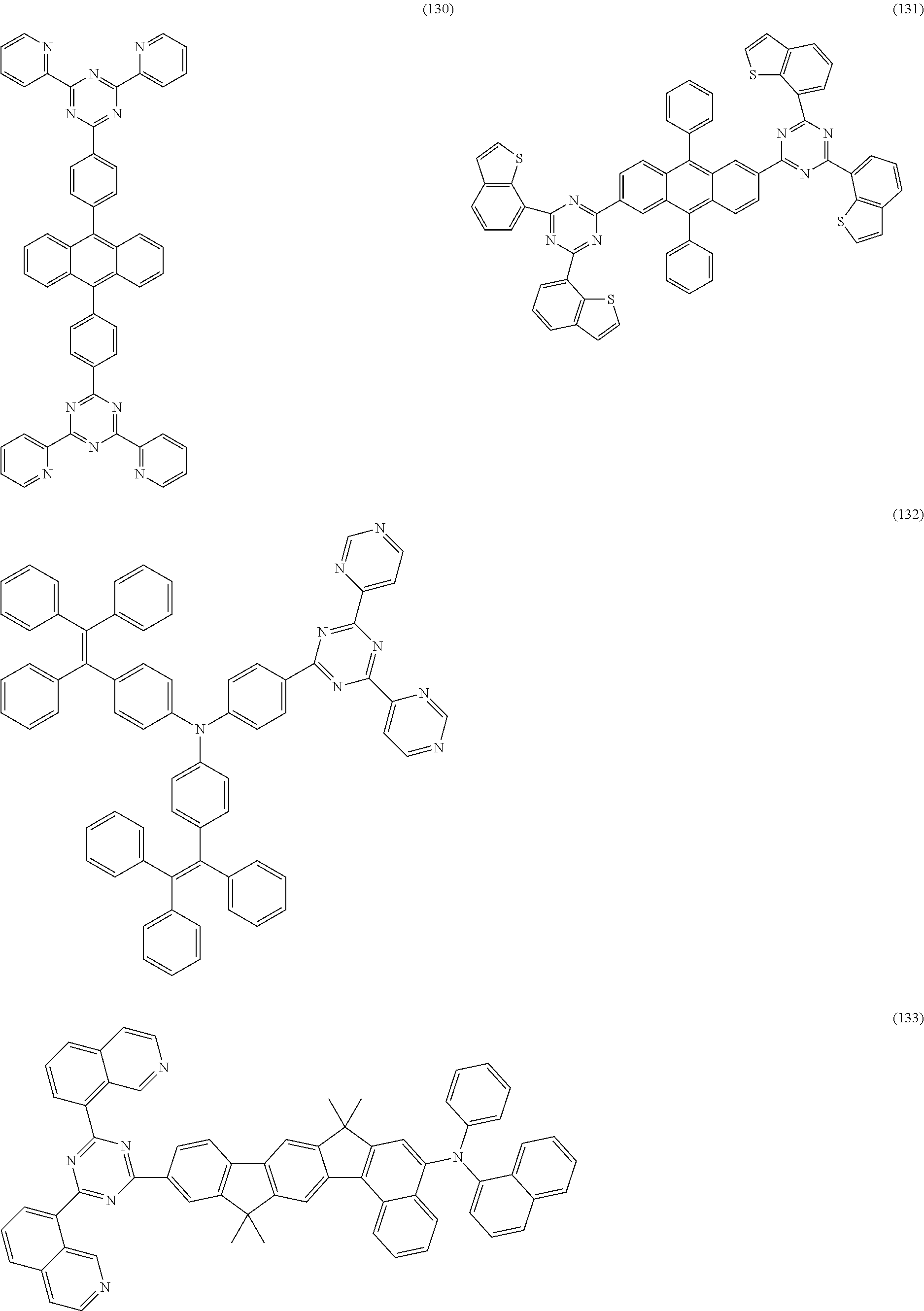 [SMILES: c1ccc(-c2nc(-c3ccc(-c4c5ccccc5c(-c5ccc(-c6nc(-c7ccccn7)nc(-c7ccccn7)n6)cc5)c5ccccc45)cc3)nc(-c3ccccn3)n2)nc1 ; c1ccc(-c2c3ccc(-c4nc(-c5cccc6ccsc56)nc(-c5cccc6ccsc56)n4)cc3c(-c3ccccc3)c3ccc(-c4nc(-c5cccc6ccsc56)nc(-c5cccc6ccsc56)n4)cc23)cc1 ; c1ccc(C(=C(c2ccccc2)c2ccc(N(c3ccc(C(=C(c4ccccc4)c4ccccc4)c4ccccc4)cc3)c3ccc(-c4nc(-c5ccncn5)nc(-c5ccncn5)n4)cc3)cc2)c2ccccc2)cc1 ; CC1(C)c2cc(-c3nc(-c4cccc5ccncc45)nc(-c4cccc5ccncc45)n3)ccc2-c2cc3c(cc21)-c1c(cc(N(c2ccccc2)c2cccc4ccccc24)c2ccccc12)C3(C)C]

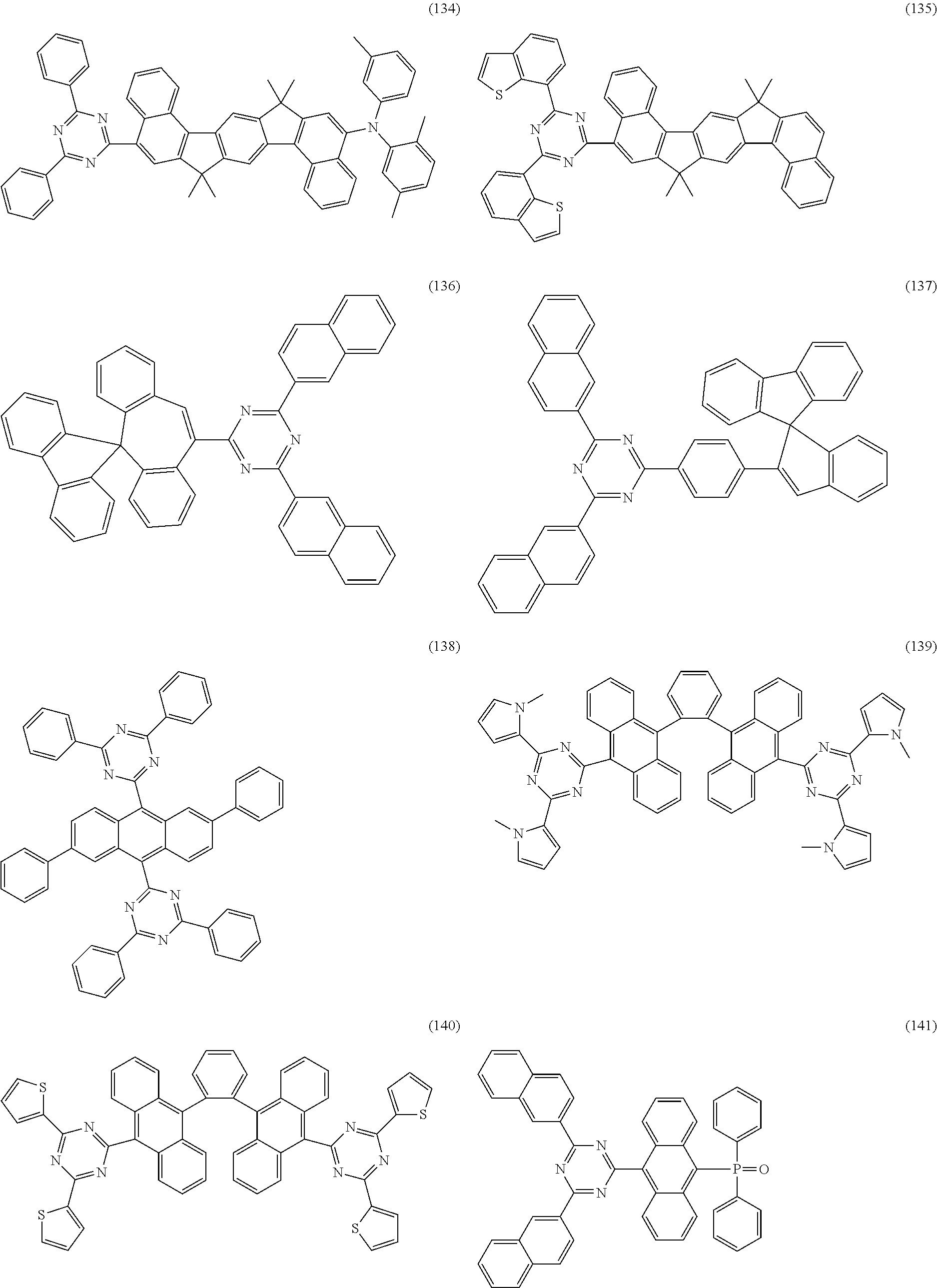

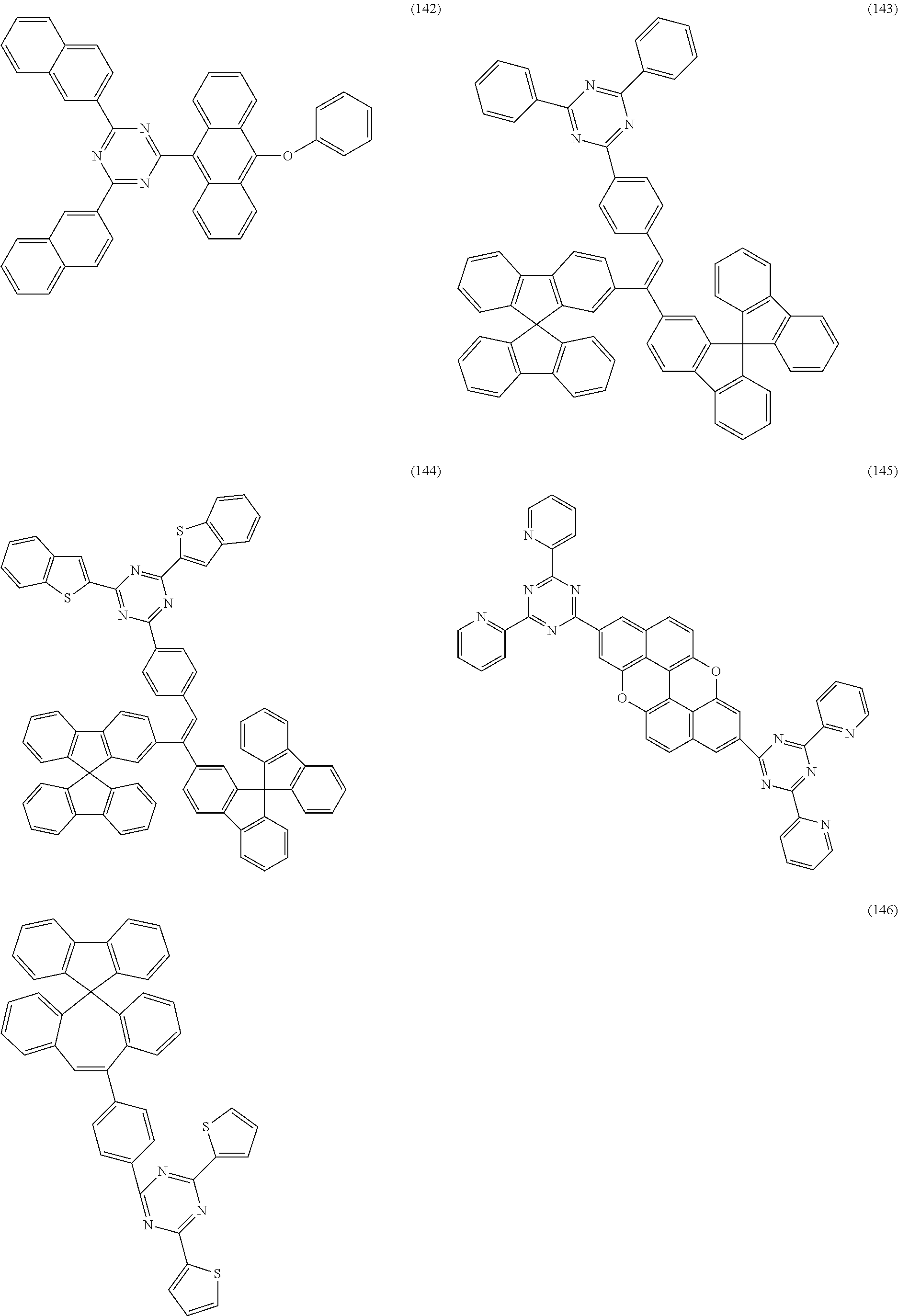

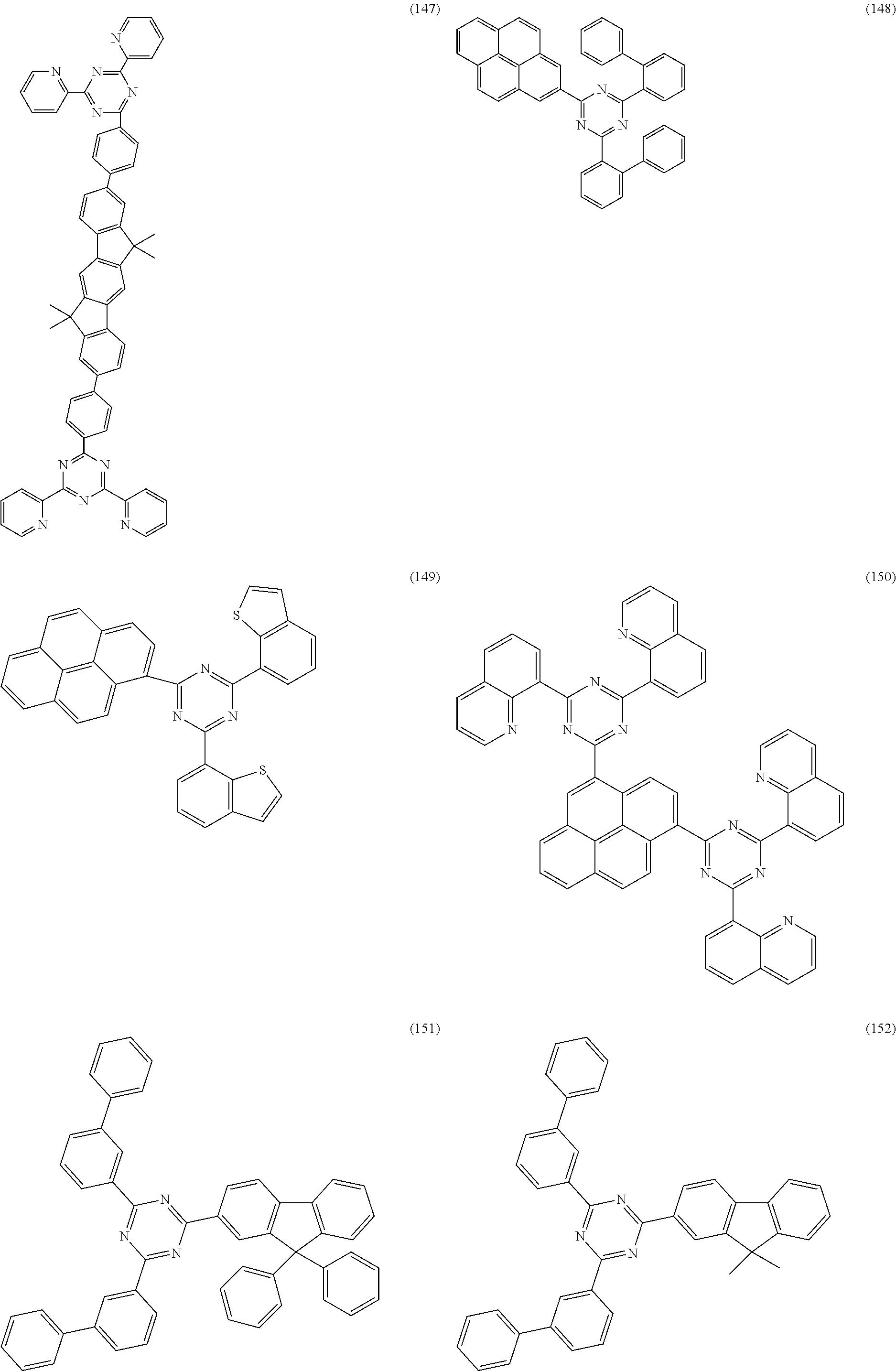

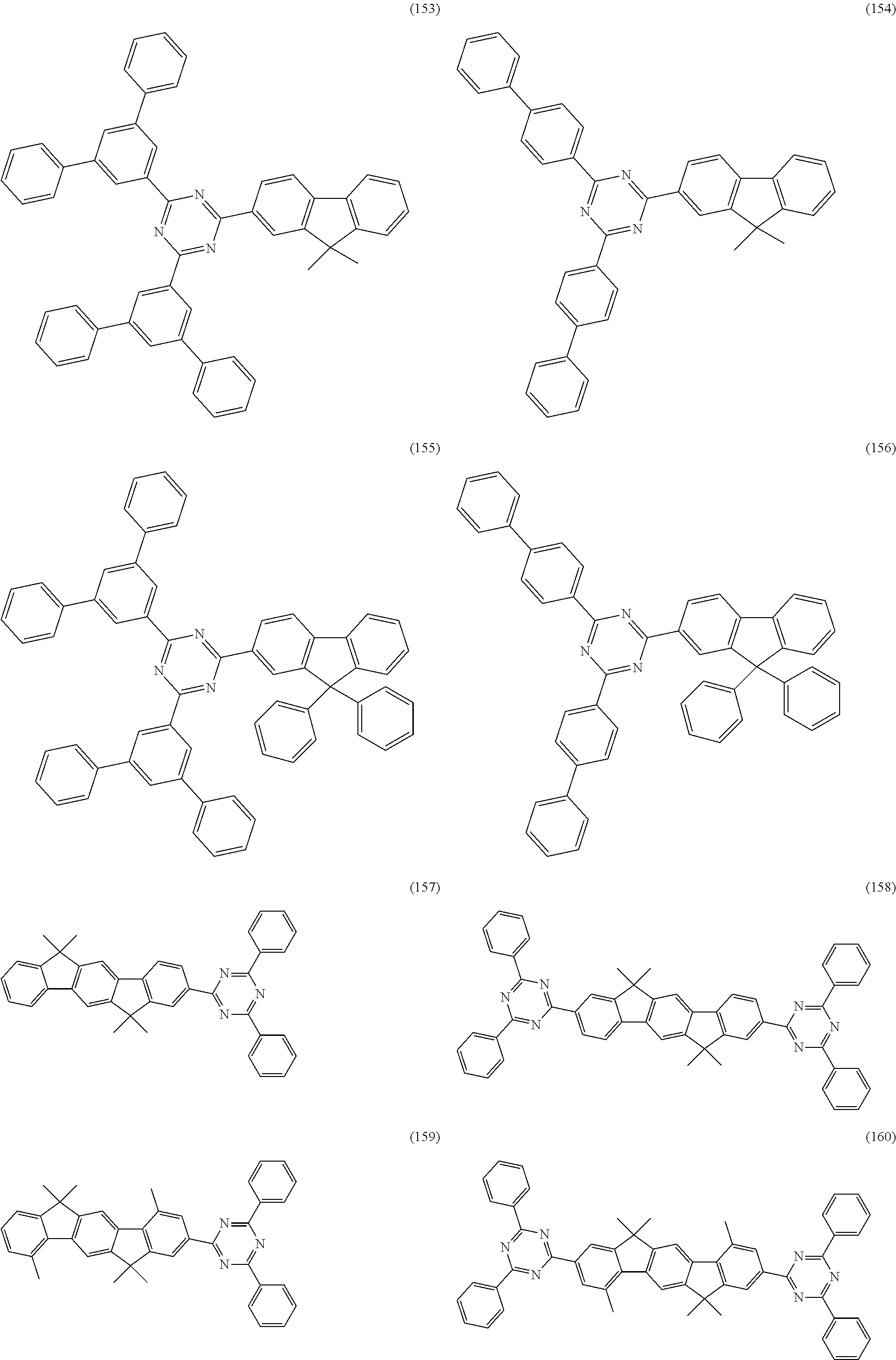

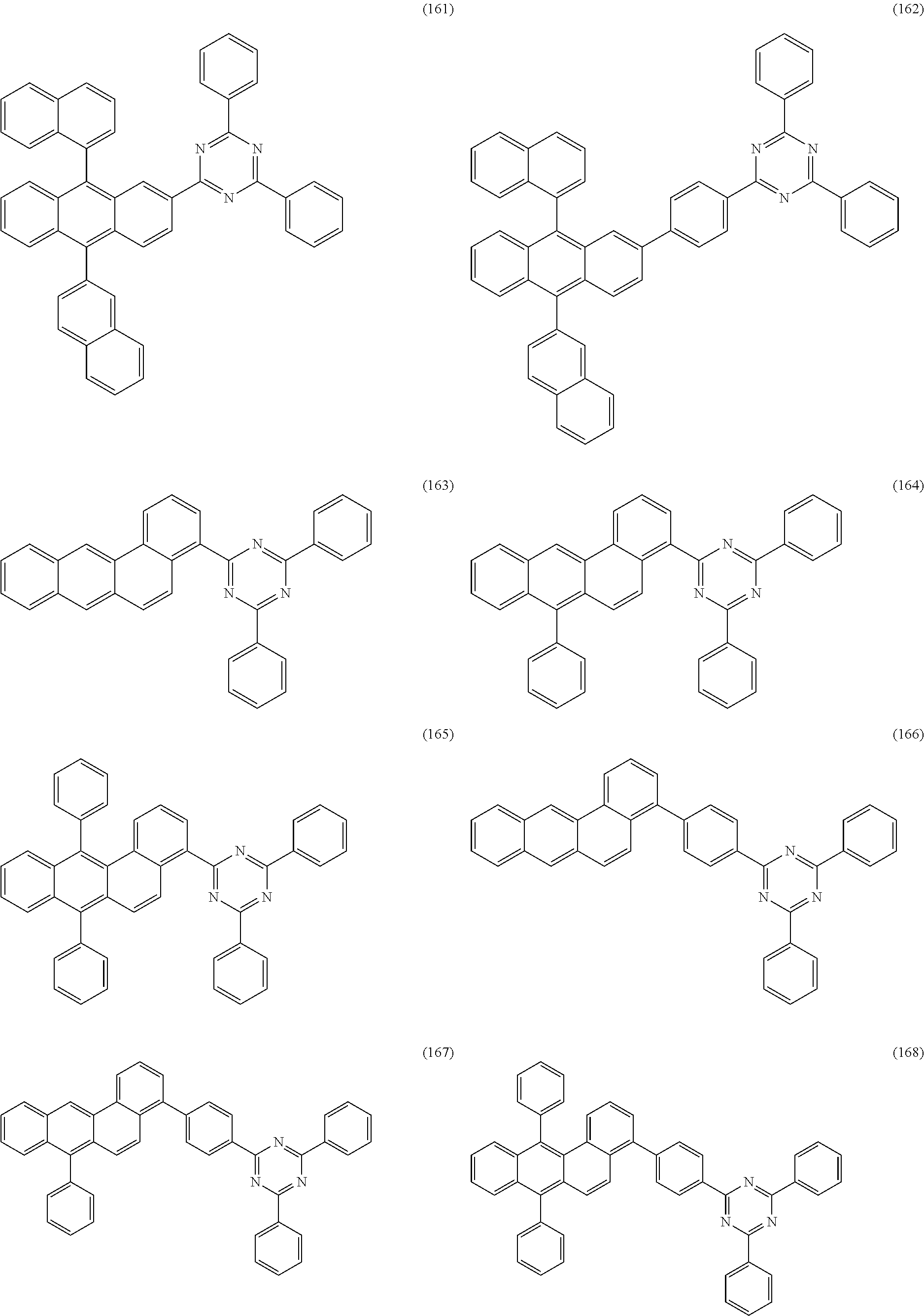

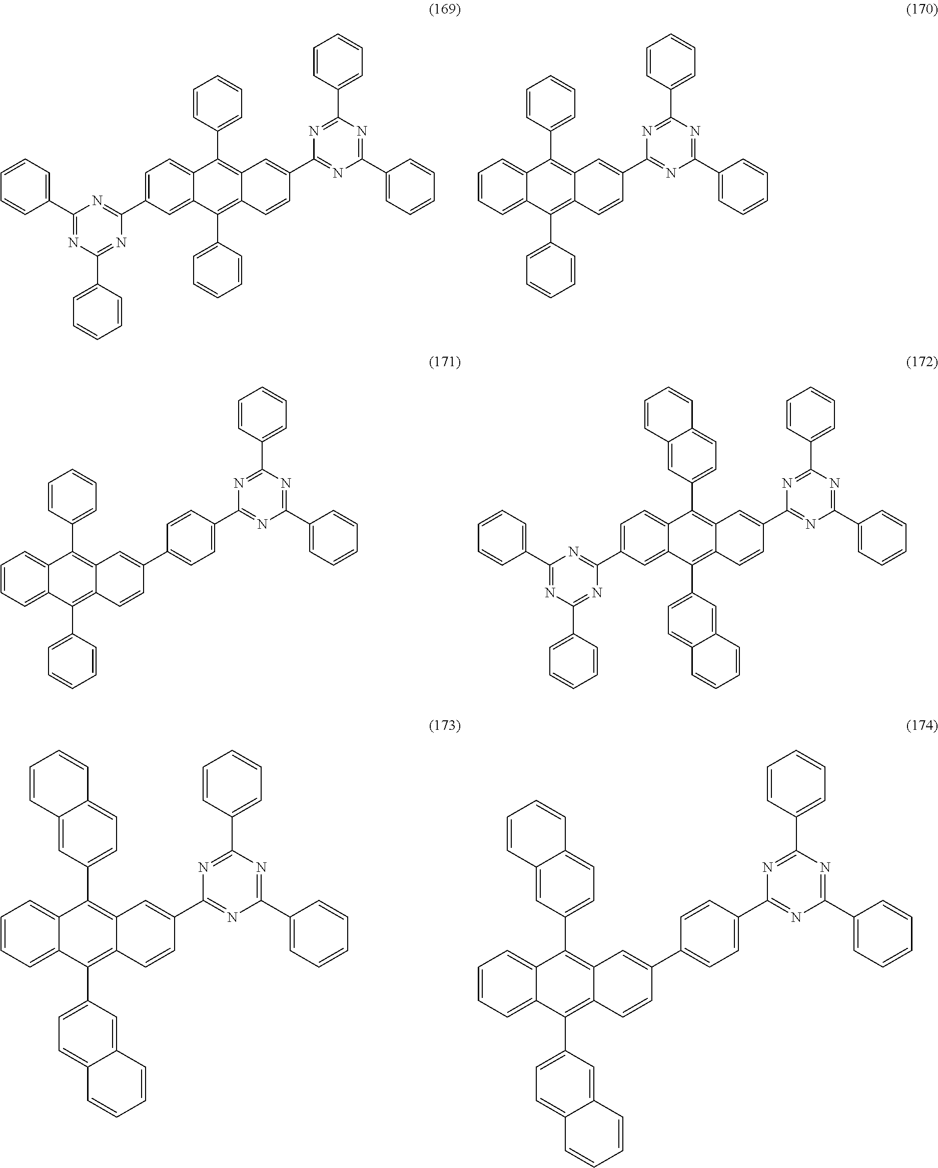

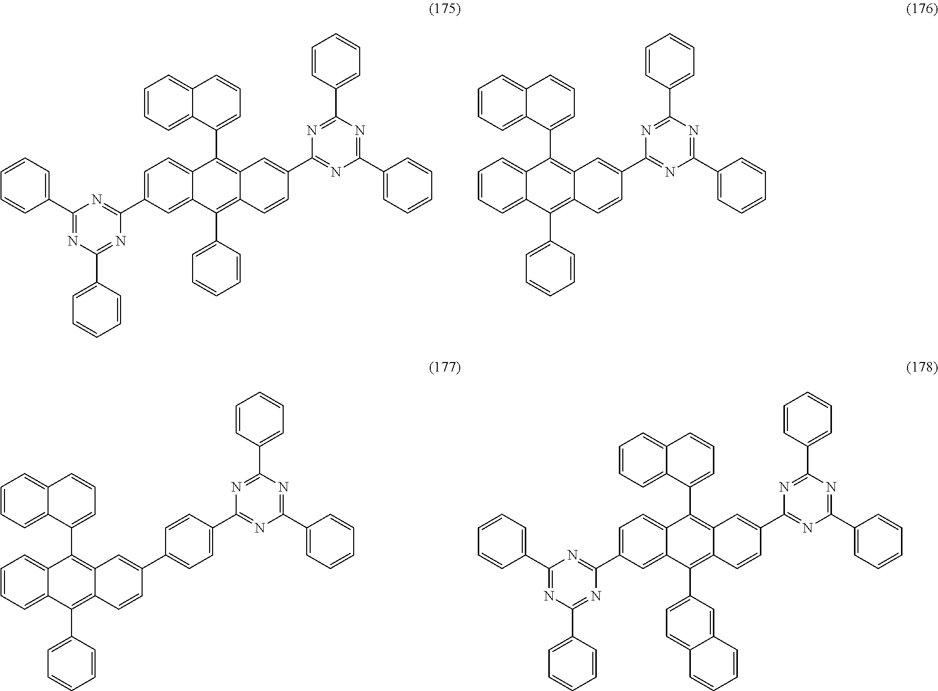 [SMILES: c1ccc(-c2nc(-c3ccccc3)nc(-c3ccc4c(-c5cccc6ccccc56)c5cc(-c6nc(-c7ccccc7)nc(-c7ccccc7)n6)ccc5c(-c5ccccc5)c4c3)n2)cc1 ; c1ccc(-c2nc(-c3ccccc3)nc(-c3ccc4c(-c5ccccc5)c5ccccc5c(-c5cccc6ccccc56)c4c3)n2)cc1 ; c1ccc(-c2nc(-c3ccccc3)nc(-c3ccc(-c4ccc5c(-c6ccccc6)c6ccccc6c(-c6cccc7ccccc67)c5c4)cc3)n2)cc1 ; c1ccc(-c2nc(-c3ccccc3)nc(-c3ccc4c(-c5cccc6ccccc56)c5cc(-c6nc(-c7ccccc7)nc(-c7ccccc7)n6)ccc5c(-c5ccc6ccccc6c5)c4c3)n2)cc1]

Materials which can be used for the electron-transport layer 2, which is directly adjacent to the cathode or the electron-injection layer, are all materials as used in accordance with the prior art as electron-transport materials in the electron-transport layer. Particularly suitable are aluminium complexes, for example Alq₃, zirconium complexes, for example Zrq₄, benzimidazole derivatives or triazine derivatives. The material used in the electron-transport layer 2 here is different from the material used in the electron-transport layer 1. Suitable materials are, for example, the materials indicated in the following table. Further suitable materials are derivatives of the compounds depicted above, as disclosed in JP 2000/053957, WO 03/060956, WO 04/028217 and WO 04/080975.

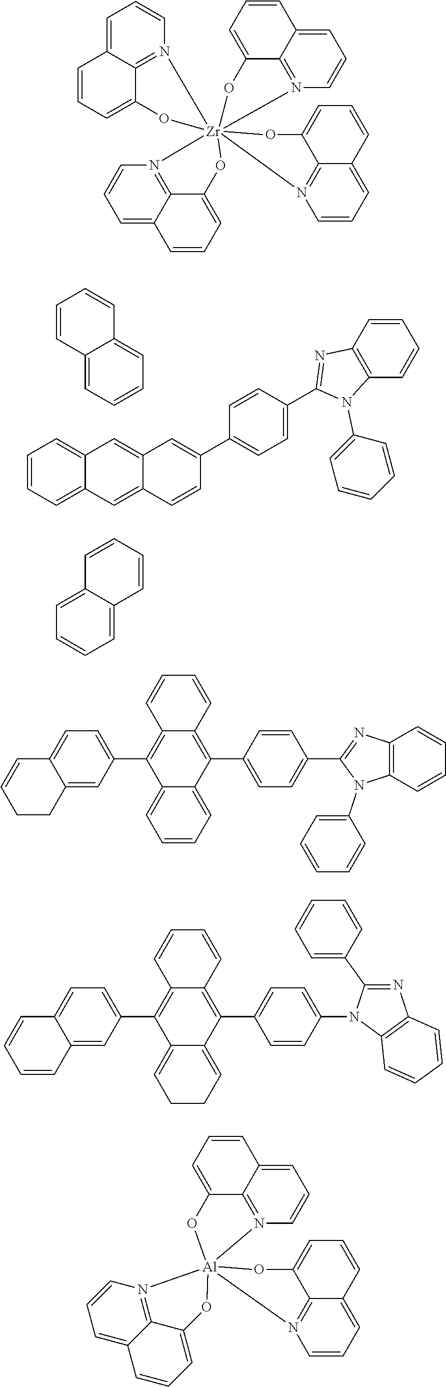

The layer thickness of the electron-transport layer 2 is preferably between 10 and 40 nm.

It is furthermore possible for the electron-transport layer 1 and/or the electron-transport layer 2 to be doped. Suitable dopants are alkali metals or alkali metal compounds, such as, for example, Liq (lithium quinolinate). In a preferred embodiment of the invention, the electron-transport layer 1 is undoped and the electron-transport layer 2 is doped or undoped. The electron-transport layer 2 here is, in particular, doped if the electron-transport material is a benzimidazole derivative or a triazine derivative. The preferred dopant is then Liq.

The cathode is preferably metals having a low work function, metal alloys or multilayered structures comprising various metals, such as, for example, alkaline-earth metals, alkali metals, main-group metals or lanthanoids (for example Ca, Ba, Mg, Al, In, Mg, Yb, Sm, etc.). In the case of multilayered structures, further metals which have a relatively high work function, such as, for example, Ag, may also be used in addition to the said metals, in which case combinations of the metals, such as, for example, Ca/Ag or Ba/Ag, are generally used. Preference is likewise given to metal alloys, in particular alloys comprising an alkali metal or alkaline-earth metal and silver, particularly preferably an alloy of Mg and Ag. It may also be preferred to introduce an electron-injection layer, i.e. a thin interlayer of a material having a high dielectric constant, between the metallic cathode and the organic semiconductor. Suitable for this purpose are, for example, alkali-metal or alkaline-earth metal fluorides, but also the corresponding oxides or carbonates (for example LiF, Li₂O, CsF, Cs₂CO₃, BaF₂, MgO, NaF, etc.), but also other alkali-metal complexes (for example lithium quinolinate). The layer thickness of this layer is usually between 0.5 and 3 nm.

The anode is preferably materials having a high work function. The anode preferably has a work function of greater than 4.5 eV vs. vacuum. Suitable for this purpose are on the one hand metals having a high redox potential, such as, for example, Ag, Pt or Au. On the other hand, metal/metal oxide electrodes (for example Al/Ni/NiOₓ, Al/PtOₓ) may also be preferred. For some applications, at least one of the electrodes must be transparent in order to facilitate either irradiation of the organic material (O-SCs) or the coupling-out of light (OLEDs/PLEDs, O-lasers). A preferred structure uses a transparent anode. Preferred anode materials here are conductive mixed metal oxides. Particular preference is given to indium tin oxide (ITO) or indium zinc oxide (IZO). Preference is furthermore given to conductive, doped organic materials, in particular conductive, doped polymers.

The device is correspondingly (depending on the application) structured, provided with contacts and finally hermetically sealed, since the lifetime of devices of this type is drastically shortened in the presence of water and/or air.

The emitting layers can be fluorescent or phosphorescent layers. In particular, the emitting layers each comprise at least one matrix material and at least one fluorescent or phosphorescent compound (dopant). It may also be preferred to use a mixture of two or more matrix materials.

For the purposes of this invention, a phosphorescent compound is a compound which exhibits luminescence from an excited state of relatively high spin multiplicity, i.e. a spin state >1, in particular from an excited triplet state, at room temperature. For the purposes of this invention, all luminescent transition-metal compounds, in particular all luminescent iridium, platinum and copper compounds, are to be regarded as phosphorescent compounds.

In a preferred embodiment of the invention, the yellow-emitting layer in electroluminescent devices having two emitting layers is a phosphorescent layer.

In a further preferred embodiment of the invention, the orange- or red-emitting layer in electroluminescent devices having three emitting layers is a phosphorescent layer.

In still a further preferred embodiment of the invention, the green-emitting layer in electroluminescent devices having three emitting layers is a phosphorescent layer.

It is particularly preferred for both the orange- or red-emitting layer and also the green-emitting layer in electroluminescent devices having three emitting layers to be phosphorescent layers. The blue-emitting layer here can be a fluorescent or phosphorescent layer. In particular, the blue-emitting layer is a fluorescent layer.

In general, all dopants and matrix materials as used in accordance with the prior art are suitable for these layers. Preferred embodiments of the materials for the emitting layers are given below.

Suitable phosphorescent compounds in the red-, orange-, green- or blue-emitting layer are, in particular, compounds which emit light, preferably in the visible region, on suitable excitation and in addition contain at least one atom having an atomic number greater than 20, preferably greater than 38 and less than 84, particularly preferably greater than 56 and less than 80. The phosphorescence emitters used are preferably compounds which contain copper, molybdenum, tungsten, rhenium, ruthenium, osmium, rhodium, iridium, palladium, platinum, silver, gold or europium, in particular compounds which contain iridium, platinum or copper.

Particularly preferred organic electroluminescent devices comprise, as phosphorescent emitter, at least one compound of the formulae (31) to (34):

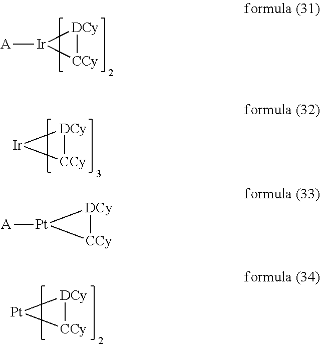

where R¹ has the same meaning as described above for formula (1), and the following applies to the other symbols used:
DCy is, identically or differently on each occurrence, a cyclic group which contains at least one donor atom, preferably nitrogen, carbon in the form of a carbene or phosphorus, via which the cyclic group is bonded to the metal, and which may in turn carry one or more substituents R¹; the groups DCy and CCy are bonded to one another via a covalent bond;
CCy is, identically or differently on each occurrence, a cyclic group which contains a carbon atom via which the cyclic group is bonded to the metal and which may in turn carry one or more substituents R¹;
A is, identically or differently on each occurrence, a monoanionic, bidentate chelating ligand, preferably a diketonate ligand.

Due to formation of ring systems between a plurality of radicals R¹, a bridge may also be present between the groups DCy and CCy. Furthermore, due to formation of ring systems between a plurality of radicals R¹, a bridge may also be present between two or three ligands CCy-DCy or between one or two ligands CCy-DCy and the ligand A, giving a polydentate or polypodal ligand system.

Examples of suitable phosphorescent emitters are revealed by the applications WO 00/70655, WO 01/41512, WO 02/02714, WO 02/15645, EP 1191613, EP 1191612, EP 1191614, WO 04/081017, WO 05/033244, WO 05/042550, WO 05/113563, WO 06/008069, WO 06/061182, WO 06/081973 and the unpublished application DE 102008027005.9. In general, all phosphorescent complexes as used in accordance with the prior art for phosphorescent OLEDs and as are known to the person skilled in the art in the area of organic electroluminescence are suitable, and the person skilled in the art will be able to use further phosphorescent compounds without inventive step. In particular, the person skilled in the art know which phosphorescent complexes emit with which emission colour.

The phosphorescent compound in the green-emitting layer here is preferably a compound of the formula (32) given above, in particular tris(phenyl-pyridyl)iridium, which may be substituted by one or more radicals R¹.

The phosphorescent compound in the orange- or red-emitting layer is preferably a compound of the formula (31), (32) or (34) given above, in particular of the formula (31).

Suitable matrix materials for the red-, orange-, green- or blue-phosphorescent emitter are various matrix materials as are known from the prior art. Suitable matrix materials are ketones, in particular compounds of the formula (1) described above for the electron-transport layer. Suitable compounds of the formula (1) are, in particular, the ketones disclosed in WO 2004/093207, WO 2004/013080, WO 2006/005627 and the unpublished DE 102008033943.1. These are incorporated into the present invention by way of reference. Further suitable matrix materials for the red-phosphorescent emitter are selected from triarylamines, carbazole derivatives, for example CBP (N,N-biscarbazolylbiphenyl), mCBP or the carbazole derivatives disclosed in WO 2005/039246, US 2005/0069729, JP 2004/288381, EP 1205527 or WO 2008/086851, indolocarbazole derivatives, for example in accordance with WO 2007/063754 or WO 2008/056746, azacarbazoles, for example in accordance with EP 1617710, EP 1617711, EP 1731584, JP 2005/347160, bipolar matrix materials, for example in accordance with WO 2007/137725, silanes, for example in accordance with WO 2005/111172, azaboroles or boronic esters, for example in accordance with WO 2006/117052, triazine derivatives, for example in accordance with the unpublished application DE 102008036982.9, WO 2007/063754 or WO 2008/056746, zinc complexes, for example in accordance with WO 2009/062578, or diazasilole and tetraazasilole derivatives, for example in accordance with the unpublished application DE 102008056688.8.

It has been found that it may have advantages to employ a plurality of matrix materials in a mixture (for example in accordance with the unpublished application DE 102008063490.5). This can have advantages, for example, with respect to the adjustability of the colour point of the white-emitting OLEDs. If a mixture of two or more matrix materials is used, they are preferably a hole-conducting matrix material and an electron-conducting matrix material. In a preferred embodiment, the green-emitting layer and/or the red-emitting layer therefore comprises at least two different matrix materials, one of which has electron-transporting properties and the other has hole-transporting properties.

The blue-emitting layer can comprise a fluorescent or phosphorescent emitter. In a preferred embodiment of the invention, the blue-emitting layer comprises at least one blue-fluorescent emitter. Suitable blue-fluorescent emitters are selected, for example, from the group of the monostyrylamines, the distyrylamines, the tristyrylamines, the tetrastyrylamines, the styrylphosphines, the styryl ethers and the arylamines. A monostyrylamine is taken to mean a compound which contains one substituted or unsubstituted styryl group and at least one, preferably aromatic, amine. A distyryl-amine is taken to mean a compound which contains two substituted or unsubstituted styryl groups and at least one, preferably aromatic, amine. A tristyrylamine is taken to mean a compound which contains three substituted or unsubstituted styryl groups and at least one, preferably aromatic, amine. A tetrastyrylamine is taken to mean a compound which contains four substituted or unsubstituted styryl groups and at least one, preferably aromatic, amine. The styryl groups are particularly preferably stilbenes, which may also be further substituted. Corresponding phosphines and ethers are defined analogously to the amines. For the purposes of this invention, an arylamine or aromatic amine is taken to mean a compound which contains three substituted or unsubstituted aromatic or heteroaromatic ring systems bonded directly to the nitrogen. At least one of these aromatic or heteroaromatic ring systems is preferably a condensed ring system, particularly preferably having at least 14 aromatic ring atoms. Preferred examples thereof are aromatic anthracenamines, aromatic pyrenamines, aromatic pyrenediamines, aromatic chrysenamines or aromatic chrysenediamines. An aromatic anthracenamine is taken to mean a compound in which a diarylamino group is bonded directly to an anthracene group, preferably in the 9-position or in the 2-position. Aromatic pyrenamines, pyrenediamines, chrysenamines and chrysenediamines are defined analogously thereto, where the diarylamino groups on the pyrene are preferably bonded in the 1-position or in the 1,6-position. Further preferred dopants are selected from indenofluoreneamines or indenofluorene-diamines, for example in accordance with WO 2006/122630, benzoindeno-fluorenamines or benzoindenofluorenediamines, for example in accordance with WO 2008/006449, and dibenzoindenofluorenamines or dibenzoindenofluorenediamines, for example in accordance with WO 2007/140847. Examples of dopants from the class of the styrylamines are substituted or unsubstituted tristilbenamines or the dopants described in WO 2006/000388, WO 2006/058737, WO 2006/000389, WO 2007/065549 and WO 2007/115610.

Suitable host materials for the blue emitters mentioned above are selected, for example, from the classes of the oligoarylenes (for example 2,2,7,7′-tetraphenylspirobifluorene in accordance with EP 676461 or dinaphthyl-anthracene), in particular the oligoarylenes containing condensed aromatic groups, the oligoarylenevinylenes (for example DPVBi or spiro-DPVBi in accordance with EP 676461), the polypodal metal complexes (for example in accordance with WO 2004/081017), the hole-conducting compounds (for example in accordance with WO 2004/058911), the electron-conducting compounds, in particular ketones, phosphine oxides, sulfoxides, etc. (for example in accordance with WO 2005/084081 and WO 2005/084082), the atropisomers (for example in accordance with WO 2006/048268), the boronic acid derivatives (for example in accordance with WO 2006/117052), the benzanthracene derivatives (for example benz[a]-anthracene derivatives in accordance with WO 2008/145239) or the benzophenanthrene derivatives (for example benzo[c]phenanthrene derivatives in accordance with the unpublished application DE 102009005746.3). Particularly preferred host materials are selected from the classes of the oligoarylenes, containing naphthalene, anthracene, benzanthracene, in particular benz[a]anthracene, benzophenanthrene, in particular benzo[c]phenanthrene, and/or pyrene, or atropisomers of these compounds. For the purposes of this invention, an oligoarylene is intended to be taken to mean a compound in which at least three aryl or arylene groups are bonded to one another.

Apart from the cathode, the anode, the emitting layers and the at least two electron-transport layers according to the invention which have been described above, the organic electroluminescent device may also comprise further layers which are not depicted in FIG. 1. These are selected, for example, from in each case one or more hole-injection layers, hole-transport layers, hole-blocking layers, further electron-transport layers, electron-injection layers, electron-blocking layers, exciton-blocking layers, charge-generation layers and/or organic or inorganic p/n junctions. In addition, interlayers may be present, which control, for example, the charge balance in the device. In particular, such interlayers may be appropriate as interlayers between two emitting layers, in particular as interlayer between a fluorescent layer and a phosphorescent layer. Furthermore, the layers, in particular the charge-transport layers, may also be doped. The doping of the layers may be advantageous for improved charge transport. However, it should be pointed out that each of these layers does not necessarily have to be present, and the choice of the layers is always dependent on the compounds used.

The use of layers of this type is known to the person skilled in the art, and he will be able, without inventive step, to use all materials in accordance with the prior art which are known for layers of this type for this purpose.

Preference is furthermore given to an organic electroluminescent device, characterised in that one or more layers are applied by means of a sublimation process, in which the materials are vapour-deposited in vacuum sublimation units at a pressure of less than 10⁻⁵ mbar, preferably less than 10⁻⁶ mbar. However, it should be noted that the pressure may also be even lower, for example less than 10⁻⁷ mbar.

Preference is likewise given to an organic electroluminescent device, characterised in that one or more layers are applied by means of the OVPD (organic vapour phase deposition) process or with the aid of carrier-gas sublimation, in which the materials are applied at a pressure between 10⁻⁶ mbar and 1 bar. A special case of this process is the OVJP (organic vapour jet printing) process, in which the materials are applied directly through a nozzle and thus structured (for example M. S. Arnold et al., Appl. Phys. Lett. 2008, 92, 053301).

Preference is furthermore given to an organic electroluminescent device, characterised in that one or more layers are produced from solution, such as, for example, by spin coating, or by means of any desired printing process, such as, for example, screen printing, flexographic printing, offset printing, LITI (light induced thermal imaging, thermal transfer printing), ink-jet printing or nozzle printing. Soluble compounds are necessary for this purpose. High solubility can be achieved through suitable substitution of the compounds. It is possible here not only for solutions of individual materials to be applied, but also solutions which comprise a plurality of compounds, for example matrix materials and dopants.

The organic electroluminescent device can also be produced as a hybrid system by applying one or more layers from solution and applying one or more other layers by vapour deposition.

These processes are generally known to the person skilled in the art and can be applied by him, without inventive step, to the organic electroluminescent devices according to the invention.

The invention furthermore relates to a process for adjusting the luminance dependence of the colour point of a white-emitting organic electroluminescent device which comprises at least two emitting layers, characterised in that at least two electron-transport layers which comprise different materials are introduced between an emitting layer and the cathode. The emitting layer on the cathode side is preferably a blue-emitting layer here. The luminance dependence of the colour point can then be adjusted or even minimised by variation of the layer thickness of the electron-transport layer which is directly adjacent to the emitting layer. The electron-transport layer here, which is directly adjacent to the emitting layer, preferably comprises an aromatic ketone, in particular a compound of the formula (1) given above.

The invention still furthermore relates to the use of at least two electron-transport layers between an emitting layer and the cathode in a white-emitting organic electroluminescent device which comprises at least two emitting layers for adjusting the luminance dependence of the colour point. The emitting layer on the cathode side is preferably a blue-emitting layer here.

The organic electroluminescent devices according to the invention have, depending on the layer thickness of the electron-transport layer 2, significantly less luminance dependence of the colour point of the emission compared with electroluminescent devices in accordance with the prior art which comprise only one electron-transport layer, i.e. the colour shift as a function of the luminance can be significantly reduced. This property is of importance if the electroluminescent device is to be operated at different luminance levels, for example for lighting applications. The other properties of the electroluminescent device according to the invention, in particular the efficiency, lifetime and operating voltage, are comparable with those of a corresponding electroluminescent device which does not comprise two electron-transport layers according to the invention.

Furthermore, the dependence of the colour point on the luminance can be adjusted specifically in the organic electroluminescent devices according to the invention. This is desirable for some applications. Although a colour shift as a function of the luminance is obtained in organic electroluminescent devices in accordance with the prior art which comprise only one electron-transport layer, this cannot, however, be adjusted specifically. By contrast, this colour shift as a function of the luminance can be adjusted specifically by variation of the layer thickness of the electron-transport layer 1.

The invention is described in greater detail by the following examples without wishing to restrict it thereby. The person skilled in the art will be able to carry out the invention throughout the range claimed, without inventive step, and thus produce further organic electroluminescent devices according to the invention.

### EXAMPLES

### Production and Characterisation of Organic Electroluminescent Devices in Accordance with the Invention

Electroluminescent devices according to the invention can be produced as described in general, for example, in WO 05/003253. The structures of the materials used are shown below for clarity.

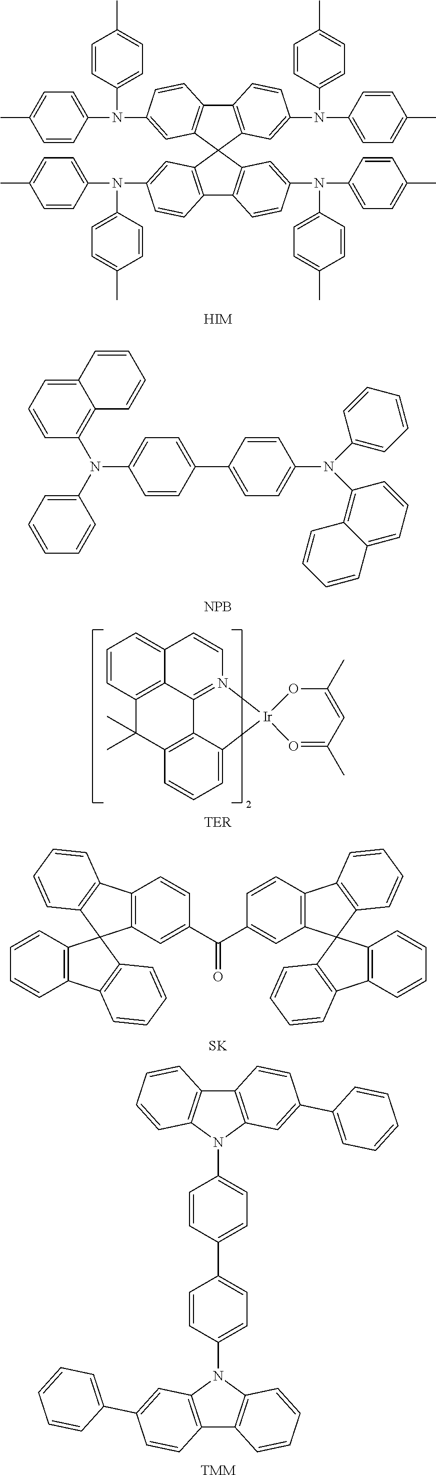

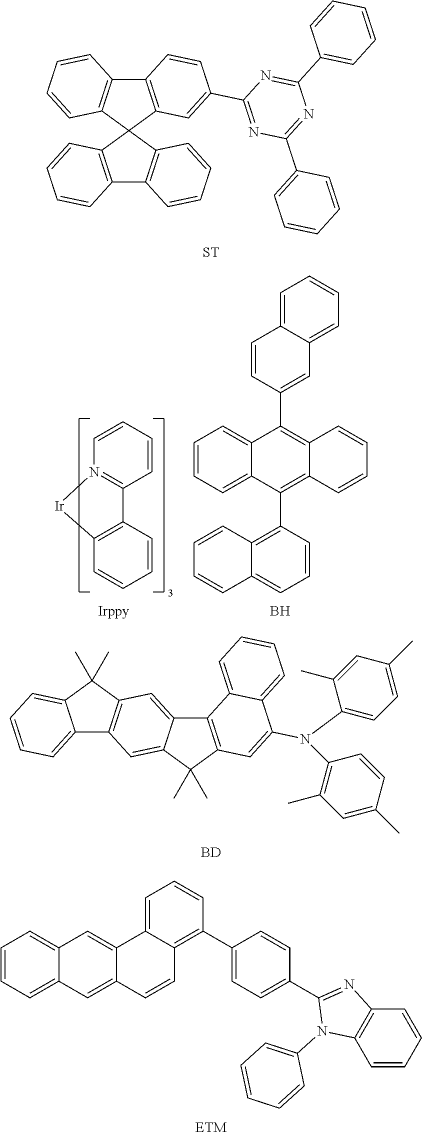

These as yet unoptimised OLEDs are characterised by standard methods; for this purpose, the electroluminescence spectra and colour coordinates (in accordance with CIE 1931), the efficiency (measured in cd/A) as a function of the luminance, the operating voltage, calculated from current/15 voltage/luminous density characteristic (IUL characteristic), and the lifetime are determined. The results obtained are shown in Table 1.

The results for various white OLEDs are compared below. The electron-conductor layer which is adjacent to the emitter layer is referred to as ETL1 below, and that which is closer to the cathode is referred to as ETL2.

### Example 1

Examples 1a, 1b and 1c according to the invention are achieved through the following layer structure:

20 nm of HIM, 20 nm of NPB, 20 nm of NPB doped with 15% of TER, 10 nm of mixed layer consisting of 70% of TMM, 10% of SK and 20% of Irppy, 25 nm of BH doped with 5% of BD, 5 nm (1a) or 10 nm (1b) or 15 nm (1c) of SK, 25 nm of ETM, 1 nm of LiF, 100 nm of Al.

The examples show that the colour shift with the luminance, measured here by comparison of the colour coordinates at 400 cd/m² and 4000 cd/m², can be adjusted specifically by varying the thickness of the ETL1 layer according to the invention consisting of SK. The OLED has a significant yellow shift with increasing luminance at 15 nm, which has already significantly reduced at 10 nm. Use of a 5 nm layer thickness enables the OLED to be operated with virtually no colour shift.

### Example 2

Example 2 is achieved through the same layer structure as Example 1c, apart from the layer thickness of the ETL2 layer being 15 nm instead of 25 nm. Comparison of Example 1c with 2 shows that variation of the layer thickness of ETL2 does not enable a significant reduction or change in the colour shift to be achieved. As shown in Example 1, this is only possible by variation of ETL1 according to the invention.

### Example 3 (Comparison)

Comparative Examples 3a, 3b and 3c are achieved through the following layer structure:

20 nm of HIM, 20 nm of NPB, 20 nm of NPB doped with 15% of TER, 10 nm of mixed layer consisting of 70% of TMM, 10% of SK and 20% of Irppy, 25 nm of BH doped with 5% of BD, 20 nm (3a) or 30 nm (3b) or 40 nm (3c) of ETM, 1 nm of LiF, 100 nm of Al.

These OLEDs comprise only one ETL and, compared with the examples according to the invention, do not comprise an additional SK layer between the blue emitter layer and the ETM layer. These OLEDs have a strong blue shift with increasing luminance. The layer thickness series 3a, 3b and 3c shows that this colour shift is, in addition, not significantly affected by variation of the ETM layer thickness.

Organic electroluminescent devices which comprise only one electron-transport layer comprising SK have very high voltages and very short life-times. This shows that the effect found is indeed associated with the use of two electron-transport layers and not with the use of a certain material.

### Example 4

Example 4 according to the invention is achieved through the following layer structure:

20 nm of HIM, 20 nm of NPB, 20 nm of NPB doped with 15% of TER, 10 nm of mixed layer consisting of 70% of TMM, 10% of SK and 20% of Irppy, 25 nm of BH doped with 5% of BD, 10 nm of ST, 25 nm of ETM, 1 nm of LiF, 100 nm of Al.

The example shows that the colour shift with luminance is also improved by an ETL1 layer consisting of ST (see comparison with Example 3a).

TABLE 1
Device results

| | | | CIE | CIE x/y at | |
|---|---|---|---|---|---|
| Ex. | ETL1 | ETL2 | x/y at 400 cd/m² | 4000 cd/m² | Delta CIE x/y |
| 1a | SK (5 nm) | ETM (25 nm) | 0.338/0.328 | 0.335/0.330 | −0.003/+0.002 |
| 1b | SK (10 nm) | ETM (25 nm) | 0.321/0.330 | 0.330/0.340 | +0.009/+0.010 |
| 1c | SK (15 nm) | ETM (25 nm) | 0.308/0.320 | 0.326/0.340 | +0.018/+0.020 |
| 2 | SK (15 nm) | ETM (15 nm) | 0.320/0.313 | 0.336/0.331 | +0.016/+0.018 |
| 3a | — | ETM (25 nm) | 0.308/0.308 | 0.285/0.289 | −0.023/−0.019 |
| 3b | — | ETM (30 nm) | 0.308/0.323 | 0.288/0.301 | −0.020/−0.022 |
| 3c | — | ETM (40 nm) | 0.320/0.334 | 0.297/0.317 | −0.023/−0.017 |
| 4 | ST (5 nm) | ETM (25 nm) | 0.350/0.354 | 0.360/0.365 | +0.010/+0.011 |

1. Organic electroluminescent device comprising, in this sequence, an anode, a yellow-, orange- or red-emitting layer, a blue-emitting layer and a cathode, characterised in that at least one electron-transport layer 1, which is adjacent to the blue-emitting layer, and an electron-transport layer 2, which is adjacent to the cathode or the electron-injection layer, are introduced between the blue-emitting layer and the cathode.

2. Organic electroluminescent device according to claim 1, characterised in that the electroluminescent device has at least three emitting layers.

3. Organic electroluminescent device according to claim 1 or 2, characterised in that the electroluminescent device emits white light having CIE colour coordinates in the range from 0.28/0.29 to 0.45/0.41.

4. Organic electroluminescent device according to one or more of claims 1 to 3, characterised in that, if the device has precisely two emitting layers, the emitting layer on the anode side is a yellow- or orange-emitting layer and in that, if the device has three emitting layers, one of these layers is a red- or orange-emitting layer and one of the layers is a green-emitting layer, where the red- or orange-emitting layer is preferably on the anode side and the green-emitting layer is between the red- or orange-emitting layer and the blue-emitting layer.

5. Organic electroluminescent device according to one or more of claims 1 to 4, characterised in that the layer thickness of the electron-transport layer 1 is in the range from 3 to 20 nm.

6. Organic electroluminescent device according to one or more of claims 1 to 5, characterised in that the electron-transport layer 1, which is directly adjacent to the blue-emitting layer, comprises an aromatic ketone, an aromatic phosphine oxide, an aromatic sulfoxide, an aromatic sulfone, a triazine derivative, a metal complex, in particular an aluminium or zinc complex, an anthracene derivative, a benzimidazole derivative, a metal benzimidazole derivative or a metal hydroxyquinoline complex.

7. Organic electroluminescent device according to claim 6, characterised in that the material for the electron-transport layer 1 is an aromatic ketone of the formula (1) 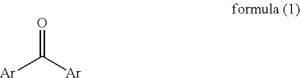
where the following applies to the symbols used:
Ar is on each occurrence, identically or differently, an aromatic or heteroaromatic ring system having 5 to 60 aromatic ring atoms, which may in each case be substituted by one or more groups R¹;
R¹ is on each occurrence, identically or differently, H, D, F, Cl, Br, I, CHO, C(═O)Ar¹, P(═O)(Ar¹)₂, S(═O)Ar¹, S(═O)₂Ar¹, CR²═CR²Ar¹, CN, NO₂, Si(R²)₃, B(OR²)₂, B(R²)₂, B(N(R²)₂)₂, OSO₂R², a straight-chain alkyl, alkenyl, alkynyl, alkoxy or thioalkoxy group having 1 to 40 C atoms or a branched or cyclic alkyl, alkenyl, alkynyl, alkoxy or thioalkoxy group having 3 to 40 C atoms, each of which may be substituted by one or more radicals R², where one or more non-adjacent CH₂ groups may be replaced by R²C═CR², C≡C, Si(R²)₂, Ge(R²)₂, Sn(R²)₂, C═O, C═S, C═Se, C═NR², P(═O)(R²), SO, SO₂, NR², O, S or CONR² and where one or more H atoms may be replaced by D, F, Cl, Br, I, CN or NO₂, or an aromatic or heteroaromatic ring system having 5 to 60 aromatic ring atoms, which may in each case be substituted by one or more radicals R², or an aryloxy or heteroaryloxy group having 5 to 60 aromatic ring atoms, which may be substituted by one or more radicals R², or a combination of these systems; two or more adjacent substituents R¹ here may also form a mono- or polycyclic, aliphatic or aromatic ring system with one another;
Ar¹ is on each occurrence, identically or differently, an aromatic or heteroaromatic ring system having 5 to 40 aromatic ring atoms, which may be substituted by one or more radicals R²;
R² is on each occurrence, identically or differently, H, D, CN or an aliphatic, aromatic and/or heteroaromatic hydrocarbon radical having 1 to 20 C atoms, in which, in addition, H atoms may be replaced by F; two or more adjacent substituents R² here may also form a mono- or polycyclic, aliphatic or aromatic ring system with one another;
or in that the material for the electron-transport layer 1 is a triazine derivative of the formula (2) or (3): 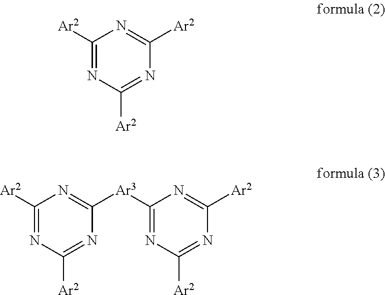
where R¹ has the meaning indicated above, and the following applies to the other symbols used:
Ar² is, identically or differently on each occurrence, a monovalent aromatic or heteroaromatic ring system having 5 to 60 aromatic ring atoms, which may in each case be substituted by one or more radicals R¹;
Ar³ is a divalent aromatic or heteroaromatic ring system having 5 to 60 aromatic ring atoms, which may be substituted by one or more radicals R¹.

8. Organic electroluminescent device according to claim 7, characterised in that the groups Ar which are bonded to the carbonyl group in formula (1) are selected from phenyl, 2-, 3- or 4-tolyl, 3- or 4-o-xylyl, 2- or 4-m-xylyl, 2-p-xylyl, o-, m- or p-tert-butylphenyl, o-, m- or p-fluorophenyl, benzophenone, 1-, 2- or 3-phenylmethanone, 2-, 3- or 4-biphenyl, 2-, 3- or 4-o-terphenyl, 2-, 3- or 4-m-terphenyl, 2-, 3- or 4-p-terphenyl, 2′-p-terphenyl, 2′-, 4′- or 5′-m-terphenyl, 3′- or 4′-o-terphenyl, p-, m,p-, o,p-, m,m-, o,m- or o,o-quaterphenyl, quinquephenyl, sexiphenyl, 1-, 2-, 3- or 4-fluorenyl, 2-, 3- or 4-spiro-9,9′-bifluorenyl, 1-, 2-, 3- or 4-(9,10-dihydro)phenanthrenyl, 1- or 2-naphthyl, 2-, 3-, 4-, 5-, 6-, 7- or 8-quinolinyl, 1-, 3-, 4-, 5-, 6-, 7- or 8-isoquinolinyl, 1- or 2-(4-methylnaphthyl), 1- or 2-(4-phenylnaphthyl), 1- or 2-(4-naphthyl-naphthyl), 1-, 2- or 3-(4-naphthylphenyl), 2-, 3- or 4-pyridyl, 2-, 4- or 5-pyrimidinyl, 2- or 3-pyrazinyl, 3- or 4-pyridazinyl, 2-(1,3,5-triazin)yl, 2-, 3- or 4-(phenylpyridyl), 3-, 4-, 5- or 6-(2,2′-bipyridyl), 2-, 4-, 5- or 6-(3,3′-bipyridyl), 2- or 3-(4,4′-bipyridyl) and combinations of one or more of these radicals, each of which may be substituted by one or more radicals R¹.

9. Organic electroluminescent device according to one or more of claims 1 to 8, characterised in that the electron-transport layer 2, which is directly adjacent to the cathode or the electron-injection layer, comprises materials selected from the group consisting of aluminium complexes, zirconium complexes, benzimidazole derivatives and triazine derivatives.

10. Organic electroluminescent device according to one or more of claims 1 to 9, characterised in that the yellow-emitting layer or the red-emitting layer and/or the green-emitting layer are phosphorescent layers, where the blue-emitting layer can in each case be a fluorescent or phosphorescent layer.

11. Organic electroluminescent device according to claim 10, characterised in that the phosphorescent emitter is selected from the compounds of the formulae (31) to (34): 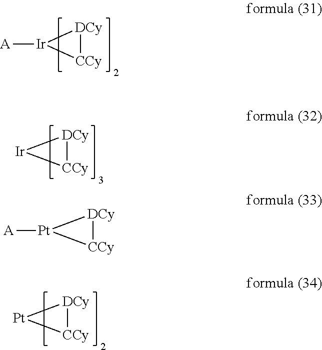
where R¹ has the same meaning as described in claim 7, and the following applies to the other symbols used:
DCy is, identically or differently on each occurrence, a cyclic group which contains at least one donor atom, preferably nitrogen, carbon in the form of a carbene or phosphorus, via which the cyclic group is bonded to the metal, and which may in turn carry one or more substituents R¹; the groups DCy and CCy are bonded to one another via a covalent bond;
CCy is, identically or differently on each occurrence, a cyclic group which contains a carbon atom via which the cyclic group is bonded to the metal and which may in turn carry one or more substituents R¹;
A is, identically or differently on each occurrence, a monoanionic, bidentate chelating ligand, preferably a diketonate ligand.

12. Organic electroluminescent device according to claim 10 or 11, characterised in that the matrix used for the phosphorescent emitter in at least one emitting layer is a mixture of a hole-conducting matrix material and an electron-conducting matrix material.

13. Process for the production of an organic electroluminescent device according to one or more of claims 1 to 12, characterised in that one or more layers are produced by means of a sublimation process, by means of the OVPD (organic vapour phase deposition) process or with the aid of carrier-gas sublimation, from solution, such as, for example, by spin coating, or by means of any desired printing process.

14. Process for reducing the luminance dependence of the colour point of a white-emitting organic electroluminescent device which comprises at least two emitting layers, characterised in that at least two electron-transport layers which comprise different materials are introduced between an emitting layer and the cathode, where the layer thickness of the layer which is directly adjacent to the emitting layer is adjusted so that the luminance dependence of the colour point adopts the desired value.

15. Use of at least two electron-transport layers between an emitting layer and the cathode in a white-emitting organic electroluminescent device which comprises at least two emitting layers for adjusting the luminance dependence of the colour point.
